(19) United States
(12) Patent Application Publication
(10) Pub. No.: US 2026/0314067 A1
(43) Pub. Date: Oct. 8, 2026

(54) SEMICONDUCTOR DEVICES HAVING GATE CONTACT AND RELATED METHODS

(71) Applicant: Taiwan Semiconductor Manufacturing Company Limited, Hsin-Chu (TW)

(72) Inventors: Anhao CHENG, Taichung City (TW); Chun-An WANG, Keelung City (TW); Chia-Wei LIU, Zhubei City (TW); Tan LO, Taipei City (TW); Szu-Chi CHAO, Hsin-Chu (TW)

(21) Appl. No.: 19/274,734

(22) Filed: Jul. 21, 2025

Related U.S. Application Data
(60) Provisional application No. 63/785,112, filed on Apr. 8, 2025.

(51) Int. Cl. H10D 84/90; H10D 89/10

(52) U.S. Cl. CPC H10D 84/966; H10D 89/10

(57) ABSTRACT

A device includes: a substrate; an isolation structure in the substrate; an active area being laterally surrounded by the isolation structure; a first gate line positioned on the substrate and overlapping the active area and the isolation structure; a second gate line immediately adjacent the first gate line; a first contact positioned on the first gate line and overlapping the isolation structure; a second contact positioned on the first gate line and overlapping the active area; a third contact positioned on the second gate line and overlapping the isolation structure; a fourth contact positioned on the second gate line and overlapping the active area; and a metal layer that includes: a first portion; a second portion that extends from the first portion and overlaps the first contact and the third contact; and a third portion that extends from the first portion and overlaps the second contact and the fourth contact.

### CROSS-REFERENCE TO RELATED APPLICATION

This application claims priority to U.S. Provisional Application 63/785,112, filed on Apr. 8, 2025, which is incorporated herein by reference.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C, and 1D illustrate side views of a device, in accordance with some embodiments.

FIGS. 2A, 2B, and 2C illustrate diagrammatic views of a method of forming a device at an intermediate stage of fabrication, in accordance with some embodiments.

FIGS. 3A, 3B, and 3C illustrate diagrammatic views of a method of forming a device at an intermediate stage of fabrication, in accordance with some embodiments.

FIGS. 4A, 4B, and 4C illustrate diagrammatic views of a method of forming a device at an intermediate stage of fabrication, in accordance with some embodiments.

FIGS. 5A, 5B, 5C, and 5D illustrate diagrammatic views of a method of forming a device at an intermediate stage of fabrication, in accordance with some embodiments.

FIGS. 6A and 6B illustrate diagrammatic views of a method of forming a device at an intermediate stage of fabrication, in accordance with some embodiments.

FIGS. 7A, 7B, 7C, and 7D illustrate diagrammatic views of a method of forming a device at an intermediate stage of fabrication, in accordance with some embodiments.

FIGS. 8A, 8B, 8C, and 8D illustrate diagrammatic views of a method of forming a device at an intermediate stage of fabrication, in accordance with some embodiments.

FIGS. 9A, 9B, 9C, 9D, 9E, and 9F illustrate diagrammatic views of a method of forming a device at an intermediate stage of fabrication, in accordance with some embodiments.

FIGS. 10A, 10B, 10C, 10D, 10E, and 10F illustrate diagrammatic views of a method of forming a device at an intermediate stage of fabrication, in accordance with some embodiments.

FIGS. 11A, 11B, and 11C illustrate diagrammatic views of a method of forming a device at an intermediate stage of fabrication, in accordance with some embodiments.

FIG. 12 is a flow diagram illustrating a method, in accordance with some embodiments.

FIG. 13 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

In high-frequency field-effect transistor (FET) devices, such as radio-frequency (RF) devices that include FETs, increasing device width can increase device speed. However, including FETs that have larger width can result in a reduced maximum frequency (fₘₐₓ) of the RF device, which can refer to a unit power gain cut-off frequency. The maximum frequency can be approximated using the following equations:

$$\\ {f}_{max} = \sqrt{\frac{{f}_{T}}{8 \times π \times {R}_{g} \times {C}_{gd}}} , \\ {f}_{T} = \frac{gm}{2 \times π \times {C}_{g}} .$$

Embodiments of the disclosure reduce alternating current (AC) gate resistance (R_{g_ac}) by including: (1) first gate contacts that overlap an isolation structure that laterally surrounds an active area of the substrate in which RF device FETs are positioned, and (2) second gate contacts that overlap the active area. Inclusion of the second gate contacts can reduce R_{g_ac}, which can result in increased fₘₐₓ of the RF device.

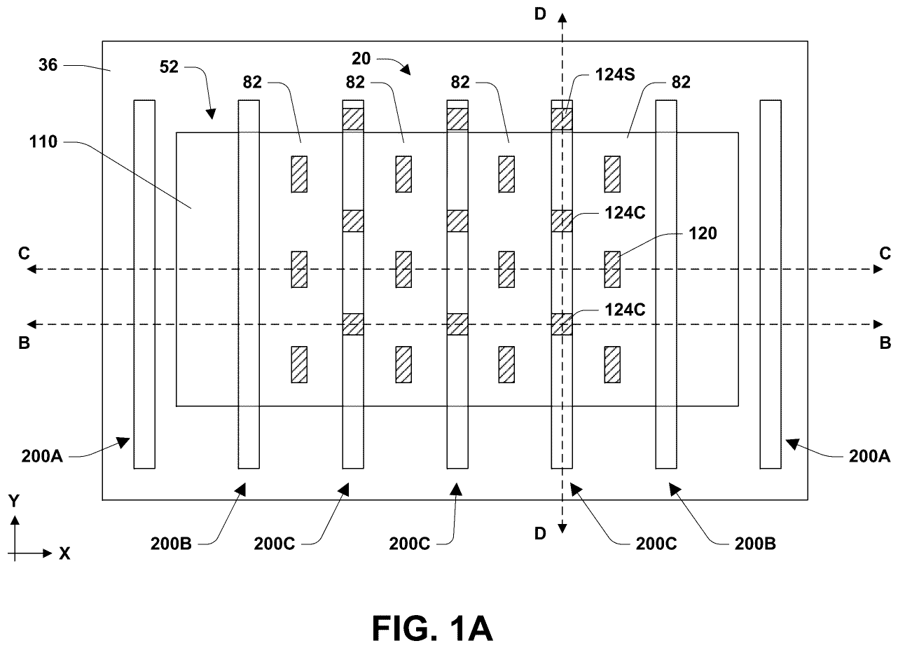

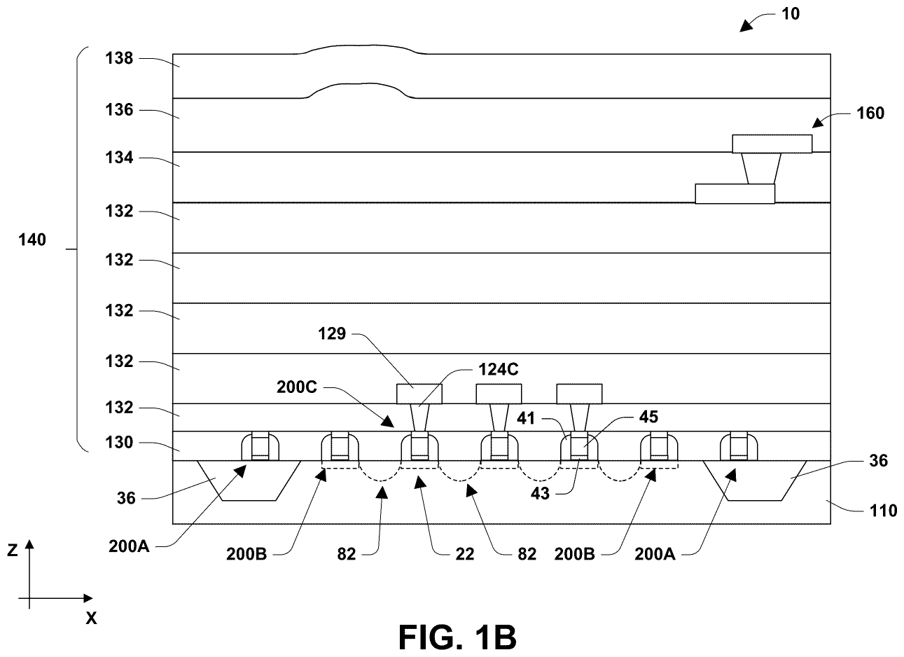

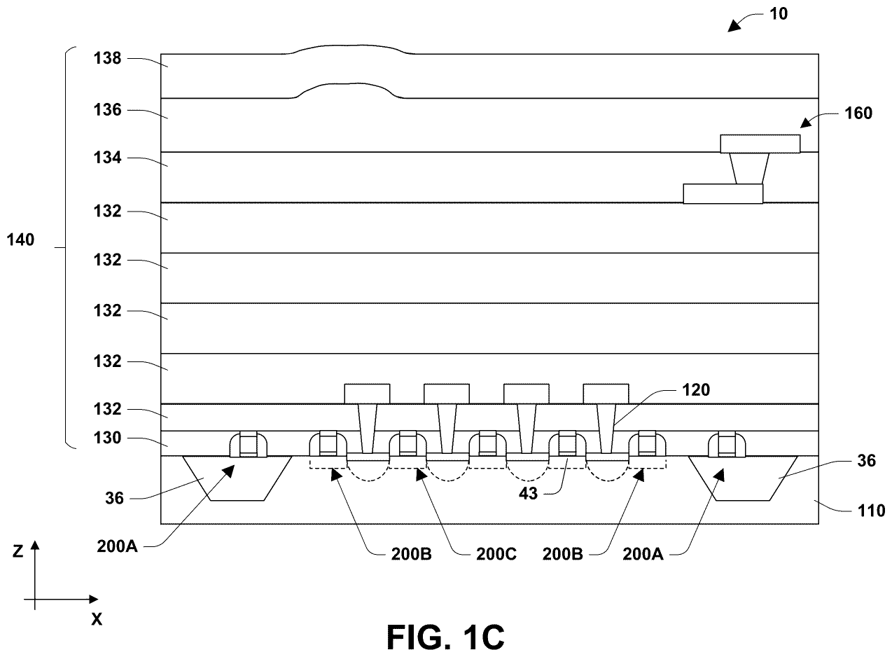

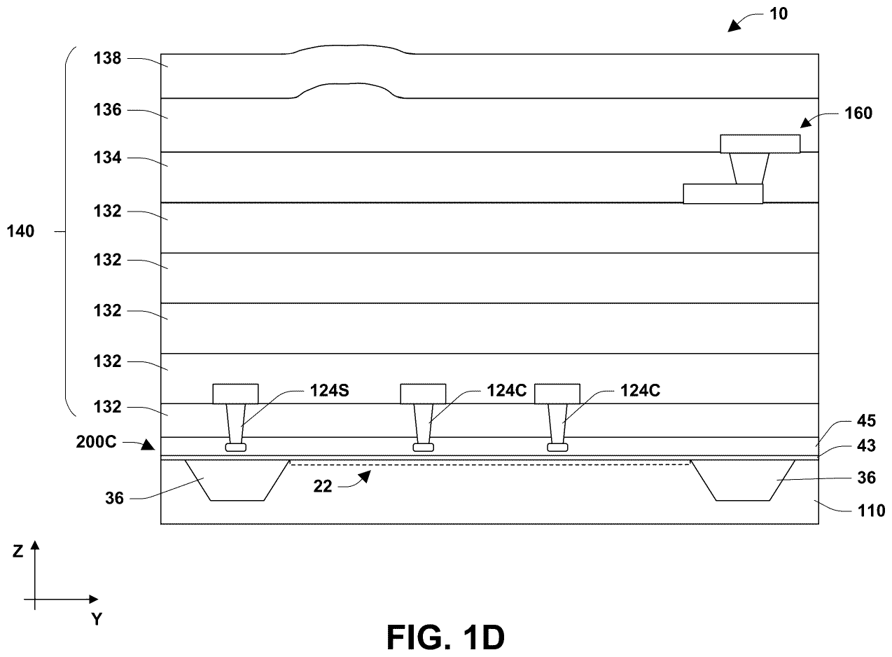

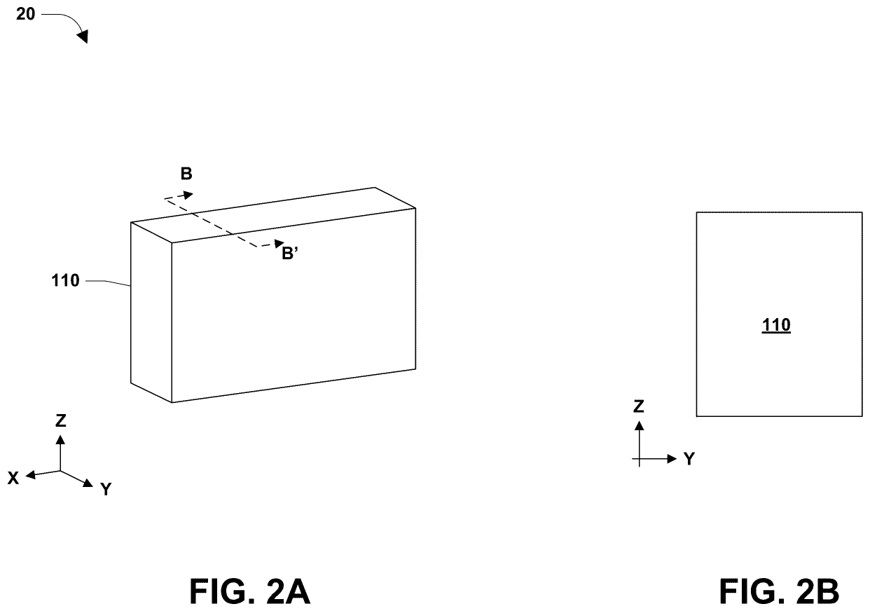

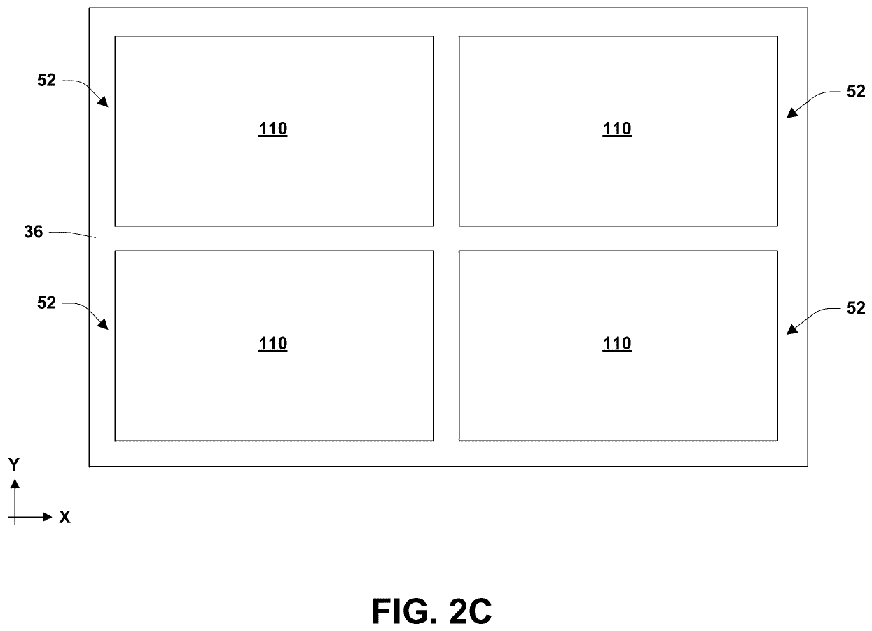

FIGS. 1A, 1B, 1C, and 1D illustrate diagrammatic plan and cross-sectional side views of a portion of an IC device 10 fabricated according to embodiments of the present disclosure, where the IC device 10 includes a RF device 20. Certain features may be removed from view intentionally in the views of FIGS. 1A-1D for simplicity of illustration. The IC device 10 is described in detail with reference to FIGS. 1A-1D to provide context for understanding the embodiments described with reference to FIGS. 2A-14.

FIG. 1A shows a portion of IC device 10 including RF device 20. The view illustrated in FIG. 1A depicts a planar field-effect transistor (FET) layout. It should be understood that embodiments of the disclosure can include fin-type FET devices, nanosheet or gate-all-around (GAA) FET devices, complementary FET devices, and the like. The RF device 20 may include an N-type FET (NFET), a P-type FET (PFET), or both, in some embodiments. The IC device 10 may include transistors having different threshold voltages based on their function in the IC device. For example, input/output (IO) transistors can have the highest threshold voltages, core logic transistors can have the lowest threshold voltages, and a third threshold voltage between that of the 10 transistors and that of the core logic transistors may also be employed for other functional transistors, such as static random-access memory (SRAM) transistors. Some circuit blocks within the IC device 10 may include two or more NFETs and/or PFETs of two or more different threshold voltages.

Referring to FIG. 1A, the RF device 20 is formed over and/or in a substrate 110, and generally includes gate structures 2000 positioned over respective semiconductor channels. The RF device 20 may be laterally surrounded by an isolation structure 36 (e.g., a shallow-trench isolation or “STI” structure).

The channels are abutted by respective source/drain regions 82. Source/drain region(s) may refer to a source or a drain, individually or collectively dependent upon the context. Each gate structure 2000 is operable to increase and/or decrease current flow between two of the source/drain regions 82 through the respective channel therebetween.

The substrate 110 is or includes at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The substrate 110 can include at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the substrate 110 are within the scope of the present disclosure.

The channels can include a semiconductive material, which can be the same semiconductive material as the substrate 110, or another appropriate semiconductive material, such as silicon or a silicon compound, such as silicon germanium, or the like.

The gate structures 2000 can be referred to as active gate structures 2000 and are operable to control flow of current between source/drains 82 via channels in the substrate 110 therebeneath. In some embodiments, the gate structures 2000 are positioned over and extend fully across an active area 52 of the substrate 110. The channels and the source/drains 82 are positioned in the active area 52.

As depicted in FIG. 1A, in some embodiments, one or more first dummy gate structures 200B is positioned adjacent the gate structures 2000 on the active area 52. The first dummy gate structure(s) 200B can improve process uniformity, reduce proximity effects and reduce edge effects, which can result in improved performance of the RF device 20 including the active gate structures 2000. The first dummy gate structure(s) 200B can be referred to as first inactive gate structures 200B. Namely, the first dummy gate structure(s) 200B can be electrically floating and not substantially carry electrical signals in operation. In some embodiments, one or more second dummy gate structures 200A is positioned adjacent the first dummy gate structure(s) 200B and fully on the isolation structure 36.

The source/drains 82 may include SiB, SiGe, SiGeB, or the like, and may include dopants, such as Ge, Sb, B, or the like. In some embodiments, the source/drain regions 82 include silicon phosphorous (SiP; Si:P), silicon arsenic (SiAs, Si:As), or the like.

The RF device 20 may include source/drain contacts 120 over one or more of the source/drains 82. The source/drain contacts 120 may include one or more liner layers and a core conductive layer (not separately illustrated in FIG. 1A). Silicide layers may be formed between the respective source/drains 82 and the source/drain contacts 120, so as to reduce source/drain contact resistance. Gate silicide layers may be formed on the respective gate lines 45. In some embodiments, the silicide layers and the gate silicide layers are or include one or more of nickel, cobalt, titanium, tantalum, platinum, tungsten, other noble metals, other refractory metals, rare earth metals, or their alloys. For example, the silicide layers and the gate silicide layers may be TiSi, TiNiSi, NiSi, WSi, CoSi, MoSi, RuSi, or the like.

FIG. 1B illustrates a diagrammatic cross-sectional view along the line B-B of FIG. 1A, in accordance with some embodiments. In FIG. 1B, the gate structures 2000 are disposed over channels 22.

In some embodiments, each of the gate structures 2000 includes a gate line 45 and a gate dielectric 43. The gate lines 45 include polysilicon or another suitable material. In some embodiments, the gate lines 45 include one or more metals or transition metal nitrides, such as W, TiN, TaN, or the like.

In some embodiments, one or more gate dielectric layers 43 is positioned between the gate lines 45 and the respective channel 22. The gate dielectric layers 43 can be or include one or more dielectric materials, such as at least one high-k gate dielectric material, which may refer to dielectric materials having a high dielectric constant that is greater than a dielectric constant of silicon oxide (k≈3.9). Exemplary high-k dielectric materials include HfO₂, HfSiO, HfSiON, HfTaO, HfTiO, HfZrO, ZrO₂, Ta₂O₅, or combinations thereof. In some embodiments, the gate dielectric layers 43 have thickness of about 5 A to about 300 A. In some embodiments, the gate dielectric layer 43 may include a non-high-k dielectric material such as silicon oxide.

The RF device 20 may include gate or “sidewall” or “outer” spacers 41 that are disposed on sidewalls of the gate lines 45. The sidewall spacers 41 can be beneficial to offset source/drain extension implants, reduce hot-carrier effects, and guide deep source/drain implants. The sidewall spacers 41 may include a dielectric material, for example SiOCN, SION, SiN, SiCN, or SiOC. In some embodiments, the sidewall spacers 41 may include one or more spacer layers. For example, as shown in FIG. 1A, the sidewall spacers 41 include one spacer layer.

FIG. 1C illustrates a cross-sectional side view along the line C-C of FIG. 1A, in accordance with some embodiments. The RF device 20 can include an interlayer dielectric (ILD) 130 on an optional etch stop layer, through which the source/drain contacts 120 extend. The ILD layer 130 provides electrical isolation between the various components of the RF device 20 discussed above, for example between gate structures 2000 and the source/drain contacts 120 therebetween. The etch stop layer may be formed prior to forming the ILD layer 130, and may be positioned laterally between the ILD layer 130 and the sidewall spacers 41 and vertically between the ILD layer 130 and the source/drain regions 82. In some embodiments, the etch stop layer is or includes SiN, SiCN, SiC, SiOC, SiOCN, HfO₂, ZrO₂, ZrAlOₓ, HfAlOₓ, HfSiOₓ, Al₂O₃, or other suitable material. In some embodiments, thickness of the etch stop layer is in a range of about 1 nm to about 5 nm.

The IC device 10 can include a frontside interconnect structure 140 that has additional interconnect conductive features 160 that overlie the source/drain contacts 120 and the ILD layer 130. In some embodiments, the interconnect conductive features 160 include conductive vias, conductive traces, or the like. The interconnect conductive features 160 can be positioned in a stack of dielectric layers, which can include intermediate ILD layers 132 on the ILD layer 130 and a top ILD layer 134 that overlies the intermediate ILD layers 132. A first passivation layer 136 may overlie the top ILD layer 134, and can be an oxide dielectric layer, in some embodiments. A second passivation layer 138 can overlie the first passivation layer 136, and can be a nitride dielectric layer. In some embodiments, as depicted in FIG. 1A, the first passivation layer 136 can smooth out non-uniformity in the underlying structure. Then, the second passivation layer 138 can further smooth out non-uniformity while also being beneficial to protect the underlying structure from moisture and contaminants, mechanical damage, and the like.

FIG. 1D illustrates a cross-sectional side view along the line D-D of FIG. 1A, in accordance with some embodiments. The RF device 20 can include first gate contacts 124S, which can be referred to as isolation gate contacts 124S. The RF device 20 can include second gate contacts 124C, which can be referred to as active area (AA) gate contacts 124C. The first gate contacts 124S are positioned over and overlap with the isolation structure 36 and extend through a bottommost layer of the intermediate ILD layers 132 and partially into the gate structure 2000, such as partially into the gate line 45. The second gate contacts 124C are positioned over and overlap with the active area 52, such as the channel 22, and extend through the bottommost layer of the intermediate ILD layers 132 and partially into the gate structure 2000, such as partially into the gate line 45.

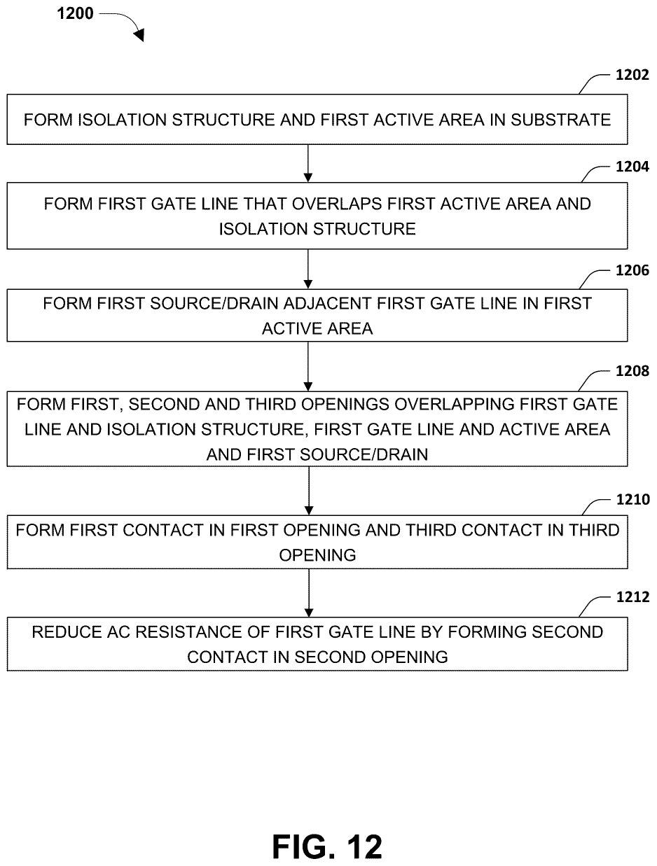

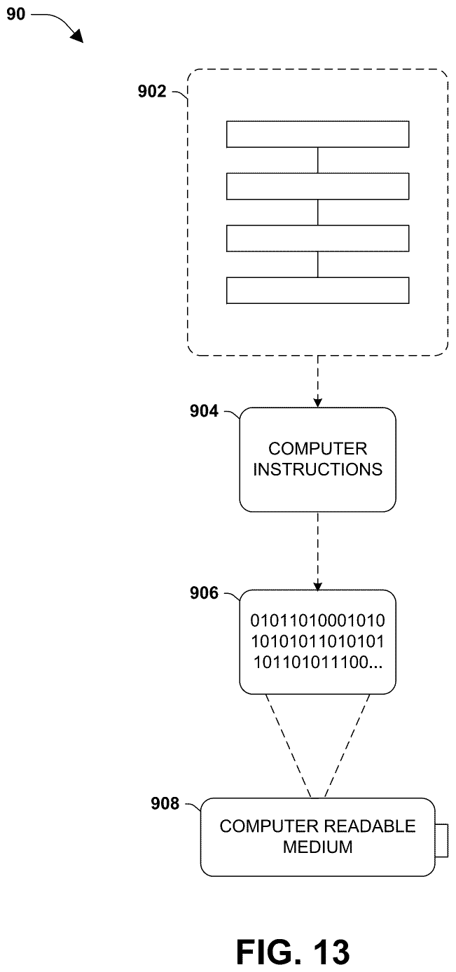

FIGS. 12 and 13 illustrate flowcharts of methods 1200, 1300 for forming an IC device or a portion thereof from a workpiece, according to one or more aspects of the present disclosure. Methods 1200, 1300 are merely examples and are not intended to limit the present disclosure to what is explicitly illustrated in methods 1200, 1300. Additional acts can be provided before, during and after the method 1200, 1300 and some acts described can be replaced, eliminated, or moved around for additional embodiments of the methods. Not all acts are described herein in detail for reasons of simplicity. Methods 1200, 1300 are described below in conjunction with fragmentary perspective and/or cross-sectional views of a workpiece, shown in FIGS. 2A-11C, at stages of fabrication according to embodiments of methods 1200, 1300. For avoidance of doubt, throughout the figures, the X-axis direction is perpendicular to the Y-axis direction and the Z-axis direction is perpendicular to both the X-axis direction and the Y-axis direction. It is noted that, because the workpiece may be fabricated into a semiconductor device, the workpiece may be referred to as the semiconductor device or simply “the device” as is beneficial to the context. The methods 1200, 1300 may be used to form the IC device 10 illustrated in FIGS. 1A-1D.

In some embodiments, the methods 1200, 1300 are performed to form a FET device. In FIGS. 2A-11C, the FET device can include a planar FET, a fin-type field-effect transistor (FinFET), or the like. In most of the figures, a planar FET is depicted as an example. The process for forming AA gate contacts 124C that overlap an active area of an RF device can be included in a process for forming a FinFET, or another suitable field-effect transistor (FET).

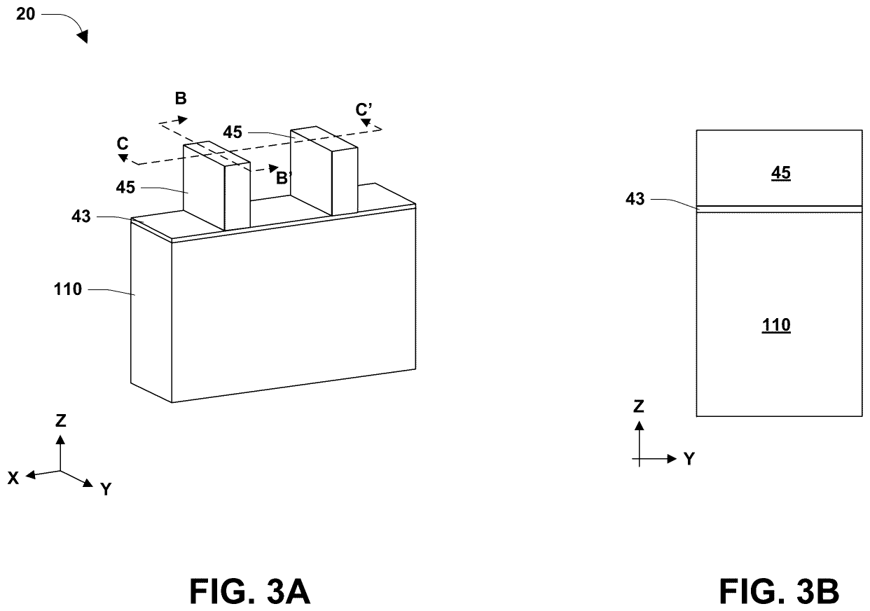

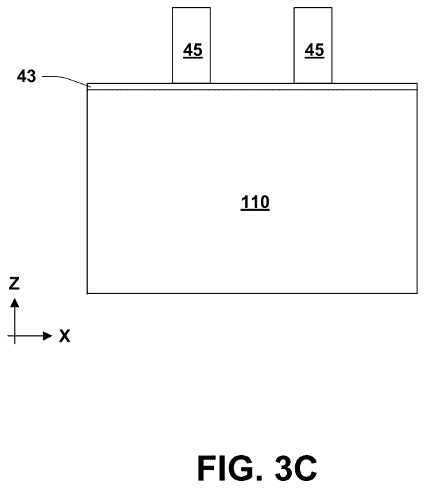

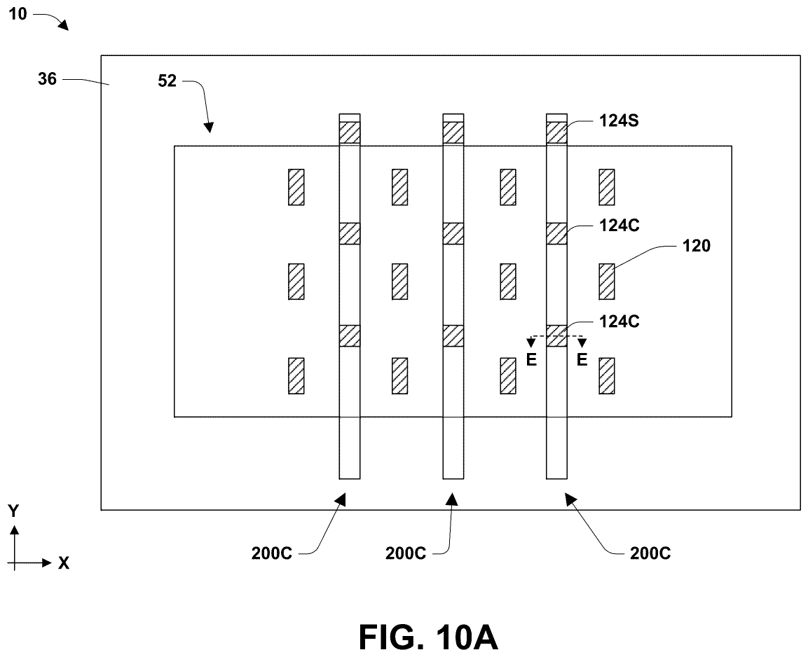

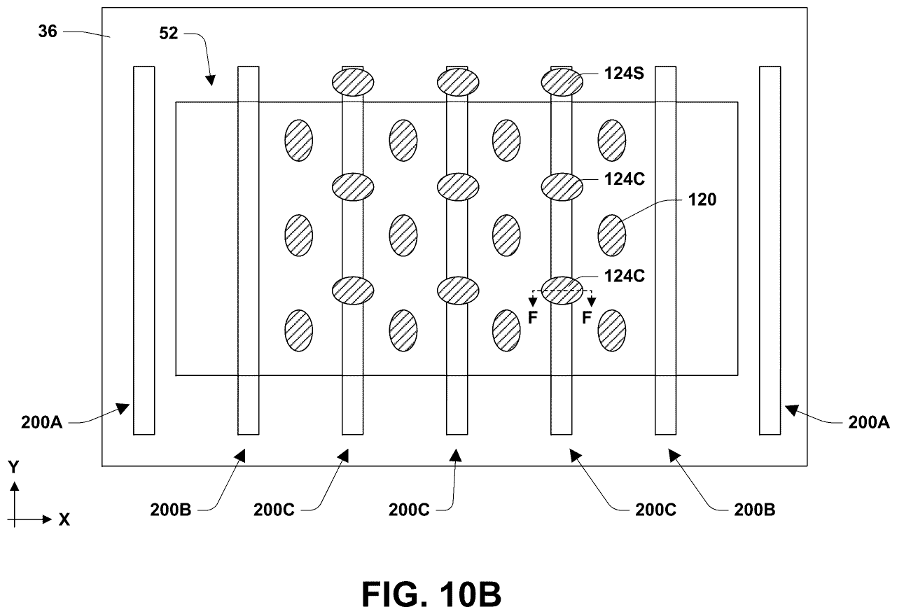

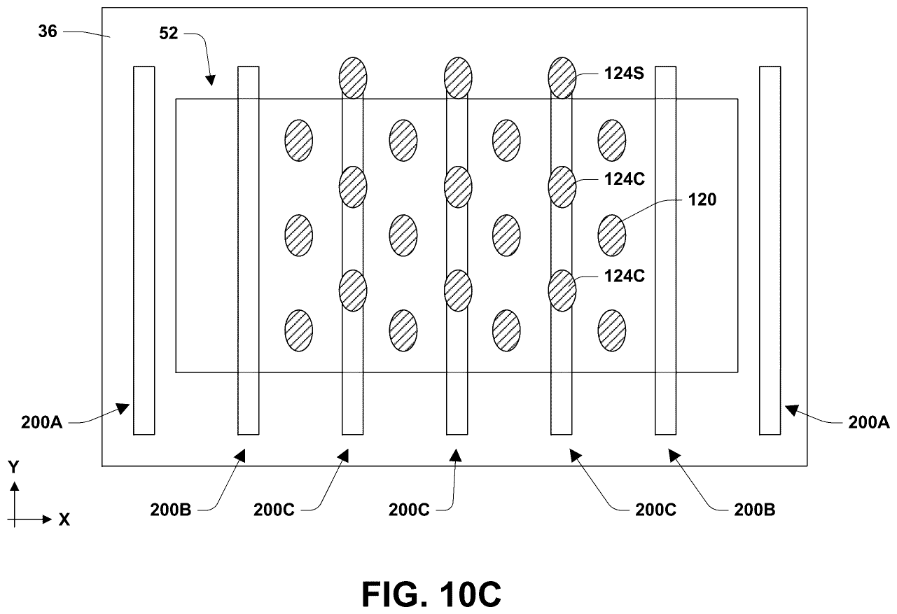

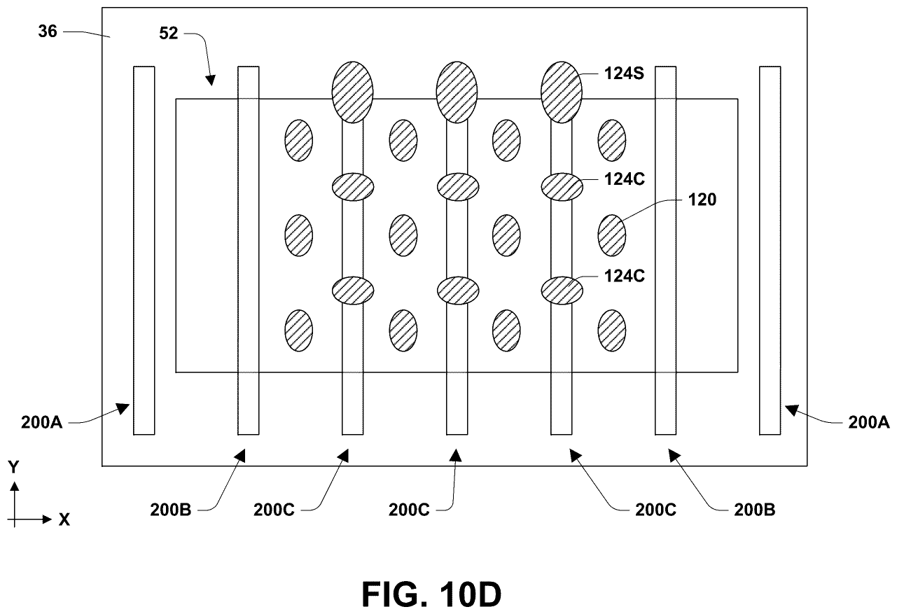

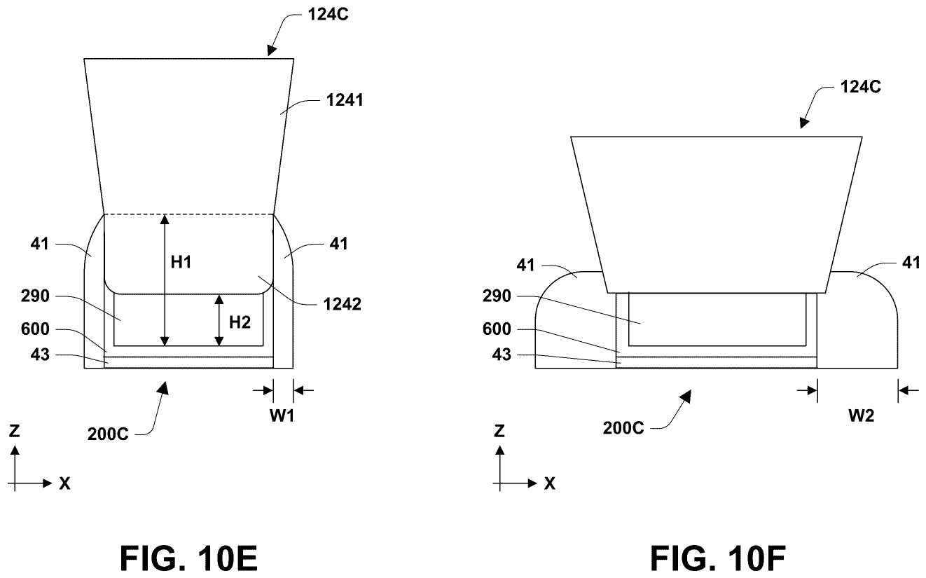

FIGS. 2A through 11C are perspective views, plan views and cross-sectional views of intermediate stages in the manufacturing of FET devices, such as a planar FET cascade device, in accordance with some embodiments. FIGS. 2A, 3A, 4A, 5A, 6A, 7A, 7C, 8A, and 8C illustrate perspective views. FIGS. 2B, 3B, 4B, 5B, 6B, 7B, 8B and 9D illustrate reference cross-section B-B′ (gate cut or “Y-cut”) illustrated in FIGS. 2A, 3A, 4A, 5A, 6A, 7A, 7C, 8A and 8C. FIGS. 3C, 4C, 5C, 8B, 8D, 9B, 9C and 9E illustrate reference cross-section C-C′ (channel cut or “X-cut”) illustrated in FIGS. 3A, 4A, 5A, 6A, 7A, 7C, 8A and 8C. FIGS. 10E and 10F illustrate reference cross-sections E-E and F-F of FIGS. 10A and 10B, respectively. FIGS. 2C, 5D, 9A, 9E, 10A, 10B, 10C, 10D, 11A, 11B, and 11C illustrate plan views.

In FIGS. 2A and 2B, a substrate 110 is provided. The substrate 110 may be any of the substrates 110 described with reference to FIGS. 1A and 1B, and can be or include a semiconductor substrate, such as a bulk semiconductor, or the like, which may be doped (e.g., with a p-type or an n-type dopant) or undoped. The semiconductor material of the substrate 110 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

In FIG. 2C, an STI region 36 is formed in the substrate 110, in accordance with some embodiments, corresponding to act 1202 of FIG. 12. In some embodiments, formation of the STI region 36 can include performing a wet chemical clean (e.g., an RCA clean) to remove organic contaminants, native oxides, and metallic impurities. Then, a thin thermal oxide (e.g., about 10 nm to about 20 nm) and a silicon nitride layer (e.g., about 100 nm to about 150 nm) can be deposited via, for example, low-pressure chemical vapor deposition (LPCVD) to protect active areas or “OD regions” 52. Photolithography can be performed to select the active areas 52, marking active areas for source, drain, and channel regions. One or more etch operations can expose the substrate 110 outside an active area mask via reactive ion etching (RIE) to form a trench(es) that can be about 200 nm to about 400 nm deep, or another suitable depth. Silicon dioxide (SiO₂) can be deposited in the trench(es) via, for example, high-density plasma CVD (HDP-CVD) to fill the trench(es). A planarization operation, such as a chemical mechanical polishing (CMP), can be performed to remove excess oxide, stopping on the silicon nitride layer. Then, the nitride layer may be stripped via hot phosphoric acid or another suitable etchant, and the oxide layer may be removed via dilute HF or another suitable etchant, leaving active areas 52 laterally surrounded by the STI region(s) 36.

In some embodiments, appropriate wells (not separately illustrated) may be formed in the active areas 52. Using masks, an n-type impurity implant may be performed in p-type regions of the substrate 110, and a p-type impurity implant may be performed in n-type regions of the substrate 110. Example n-type impurities may include phosphorus, arsenic, antimony, or the like. Example p-type impurities may include boron, boron fluoride, indium, or the like. An anneal may be performed after the implants to repair implant damage and to activate the p-type and/or n-type impurities.

In FIGS. 3A-3C, the gate lines 45 are formed over the substrate 110 on the active areas 52 and extending onto the isolation structure 36, corresponding to act 1204 of FIG. 12. The gate lines 45 may be a semiconductive, conductive, or non-conductive material and may be or include one or more of amorphous silicon, polycrystalline-silicon (polysilicon), poly-crystalline silicon-germanium (poly-SiGe), metallic nitrides, metallic silicides, metallic oxides, and metals. The gate lines 45 may be deposited by physical vapor deposition (PVD), CVD, sputter deposition, or other techniques suitable for depositing the selected material. In some embodiments, one or more mask layers are formed over the gate lines 45, and may include, for example, silicon nitride, silicon oxynitride, or the like. In some embodiments, the gate dielectric layer 43 is formed before the gate lines 45 and is positioned between the gate lines 45 and the substrate 110. In some embodiments, the gate lines 45 are replaced in a subsequent process. In some embodiments, the gate lines 45 are not replaced.

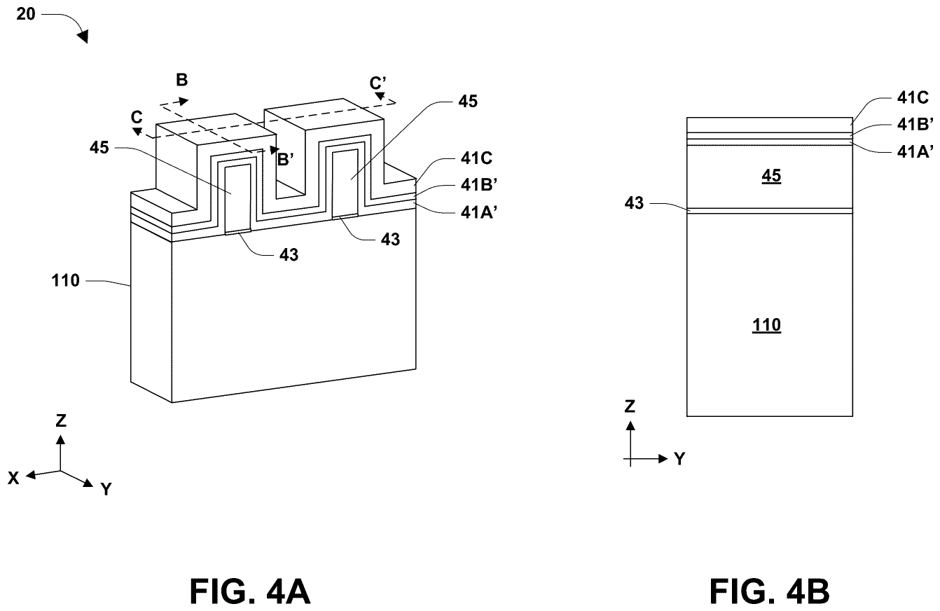

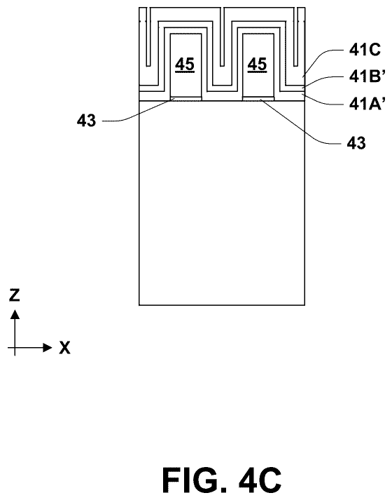

In FIGS. 4A-4C, one or more spacer layers 41A′, 41B′ are formed over the gate lines 45. The spacer layers 41A′, 41B′ can be or include an insulating material, such as silicon nitride, silicon oxide, silicon carbo-nitride, silicon oxynitride, silicon oxy carbo-nitride, or the like, and may have a single-layer structure or a multi-layer structure including a plurality of dielectric layers, in accordance with some embodiments. FIGS. 4A-4C depict a first spacer layer 41A′ and a second spacer layer 411B′ on the first spacer layer 41A′. In some embodiments, the first spacer layer 41A′ and the second spacer layer 41B′ are different materials as each other or the same material as each other. A mask layer 41C is formed on the spacer layer 41B′. In some embodiments, prior to forming the spacer layers 41A′, 41B′, the gate dielectric layer 43 is trimmed by removing portions of the gate dielectric layer 43 exposed by the gate lines 45.

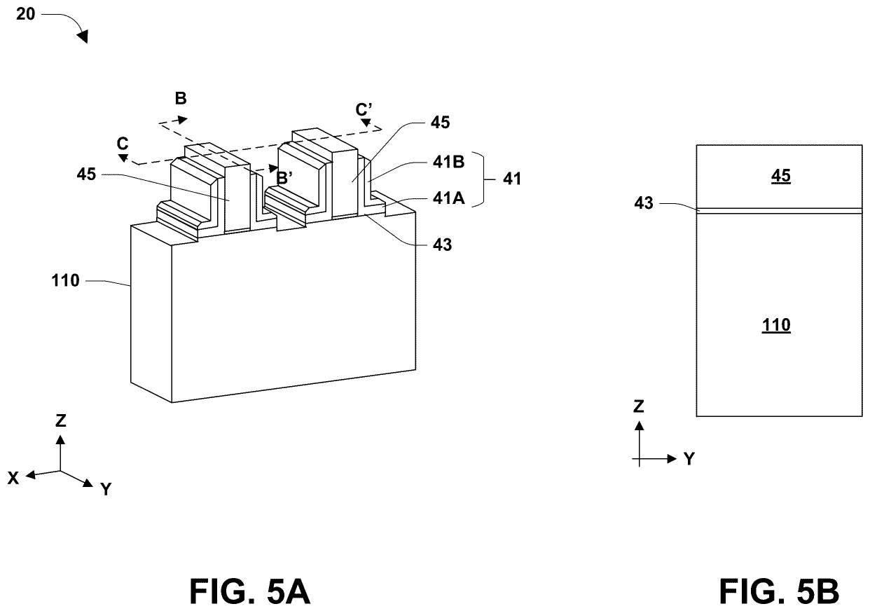

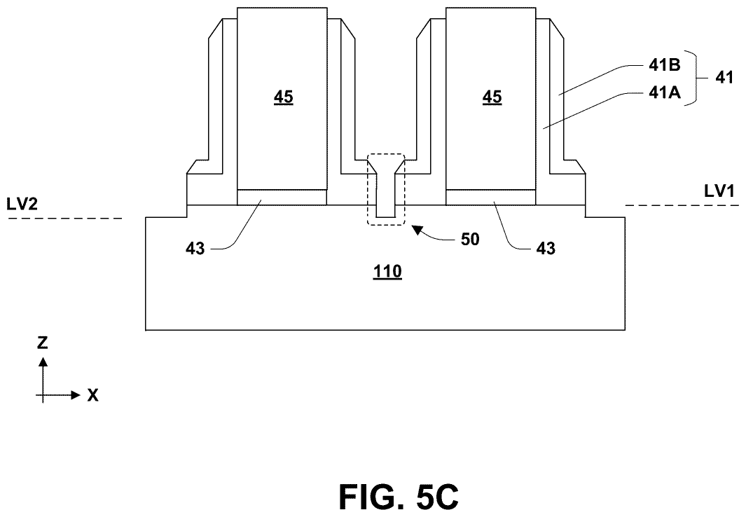

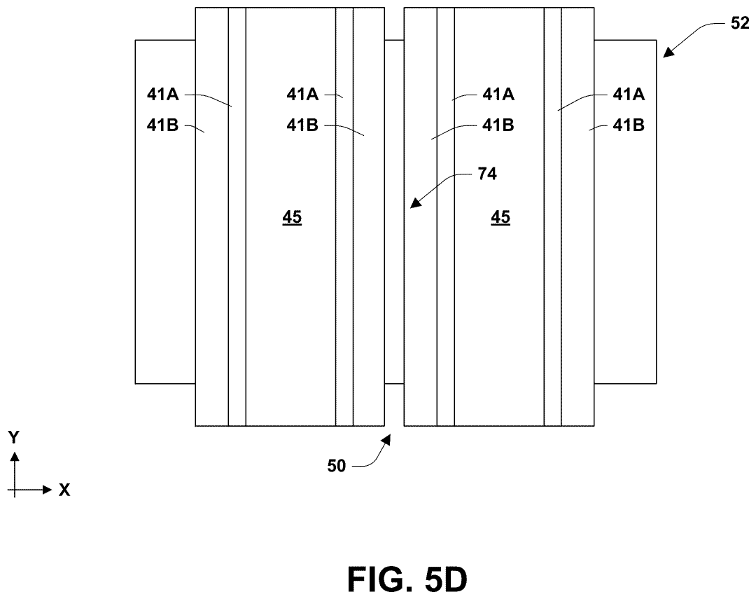

In FIGS. 5A-5D, the sidewall spacers 41 are formed that include first spacers 41A and second spacers 41B on the first spacers 41A. Referring to FIGS. 5A and 5B, forming the sidewall spacers 41 can include removing portions of the spacer layers 41A′, 41B′ between the gate lines 45 by one or more anisotropic etching processes, in accordance with some embodiments. In some embodiments, the sidewall spacers 41 have upper surfaces that are recessed from upper surfaces of the gate lines 45. For example, the gate lines 45 may protrude upward from the sidewall spacers.

In FIG. 5C, in some embodiments, the substrate 110 exposed by the sidewall spacers 41 is etched slightly, which can also be referred to as overetching. As a result, first portions of the substrate 110 directly under the sidewall spacers 41, the gate dielectric layer 43 and the gate lines 45 have upper surfaces at a first level LV1 that is above a second level LV2 of an upper surface of the substrate 110 that is exposed by the sidewall spacers 41.

FIGS. 5C and 5D depict an opening 50 that is defined between sidewalls of the sidewall spacers 41 between a neighboring pair of the gate lines 45. The opening 50 exposes a first exposed area 74 of the substrate 110. Because the opening 50 is narrow in the X-axis direction due to being between the neighboring pair of gate lines 45 of the RF device 20, source/drain regions and silicide layers formed in the first exposed area 74 in subsequent operations may have high resistance, which can result in device failure and low yield.

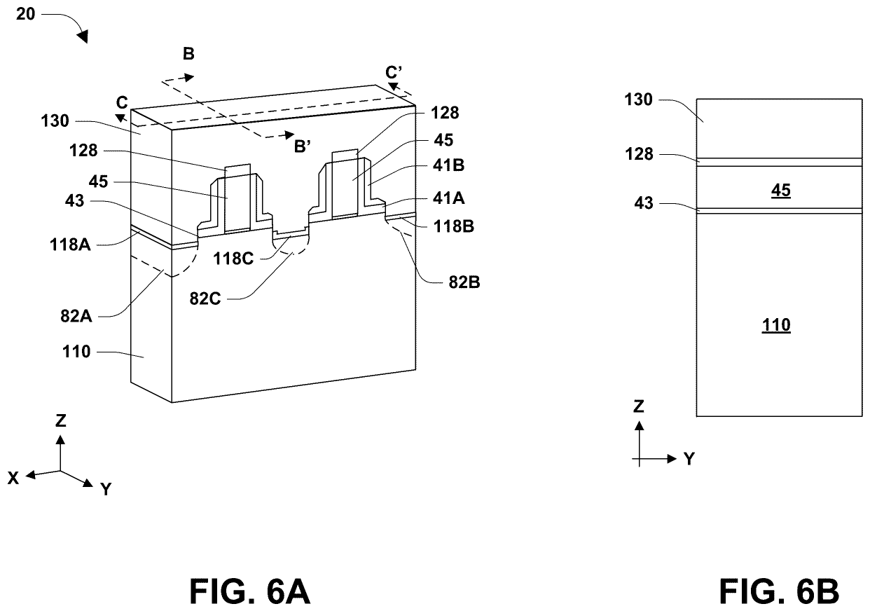

FIGS. 6A and 6B illustrate views of forming source/drains 82A, 82B, 82C and the ILD layer 130, corresponding to act 1206 of FIG. 12.

The source/drain regions 82A, 82B, 82C can be formed by a suitable implantation operation that implants N-type or P-type dopants in exposed regions of the substrate 110. For example, following formation of the sidewall spacers 41, the exposed surface of the substrate 110 can be cleaned to remove contaminants or native oxide, which can include wet chemical cleaning (e.g., dilute HF) or plasma-based cleaning. Then, a shallow, low-energy ion implantation can be performed to form lightly doped drain (LDD) or source/drain extension regions. For N-type MOS (NMOS) devices, dopants including phosphorus or arsenic can be implanted. For P-type MOS (PMOS) devices, dopants including boron or BF₂ can be implanted. The gate lines 45 and sidewall spacers 41 can act as a mask, improving alignment of the extensions with gate edges. In some embodiments, a low-temperature anneal may be performed to activate dopants and repair implantation damage. Then, a higher-energy, higher-dose ion implantation can be performed to form heavily doped source/drain regions 82A, 82B, 82C. In some embodiments, for NMOS devices, arsenic or phosphorus can be implanted at higher doses (e.g., 10¹⁵ cm⁻² to 10¹⁶ cm⁻²). In some embodiments, for PMOS devices, boron or BF₂ can be implanted at similar doses. The gate lines 45 and the sidewall spacers 41 can again act as a self-aligned mask, improving offset of the source/drain regions 82A, 82B, 82C from respective channels by width of the sidewall spacers 41. Implant parameters (e.g., energy, dose, angle) can be selected to achieve a selected junction depth, doping profile, and sheet resistance. A thermal anneal can be performed to activate the implanted dopants (e.g., to incorporate the dopants into a silicon lattice) and repair crystalline damage caused by implantation. For example, a rapid thermal annealing (RTA) can be performed that includes a short, high-temperature process (e.g., 900° C. to 1100° C. for seconds) to reduce dopant diffusion. In some embodiments, a shorter, high-temperature pulse or “spike annealing” can be performed to reduce diffusion. Laser or flash annealing including rapid heating can be performed to activate dopants with reduced thermal budget. A final cleaning step can remove any residues or surface damage from implantation or annealing, preparing the source/drain regions 82A, 82B, 82C for subsequent operations that can include RPO deposition, salicide (self-aligned silicide) formation, and contact formation.

Following formation of the source/drain regions 82A, 82B, 82C and prior to formation of source/drain contacts 120, a resist protection oxide (RPO) operation may be performed that forms an RPO. The RPO is not separately illustrated in the Figures. Formation of the RPO can protect one or more areas from silicidation during a subsequent salicide process. The RPO can also serve as a barrier during contact etching to prevent over-etching into sensitive regions. A thin layer of oxide (e.g., 10 nm to 50 nm) can be deposited using plasma-enhanced chemical vapor deposition (PECVD), low-pressure CVD (LPCVD) or the like. Then, photolithography can be performed to pattern a photoresist mask over areas where silicide formation is not selected (e.g., for high-resistance polysilicon resistors or some selected source/drain regions). The RPO layer can be etched selectively (e.g., using a dry etch, such as reactive ion etching) in areas where silicide is to be formed, such as the source/drain regions 82A, 82B, 82C, gate lines 45 or both. The photoresist is stripped, leaving the RPO in protected areas.

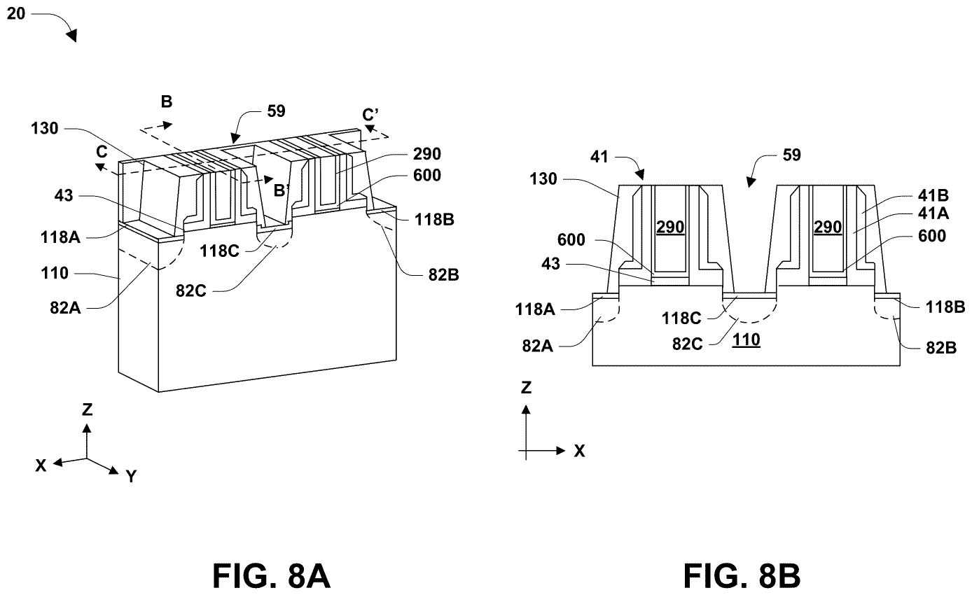

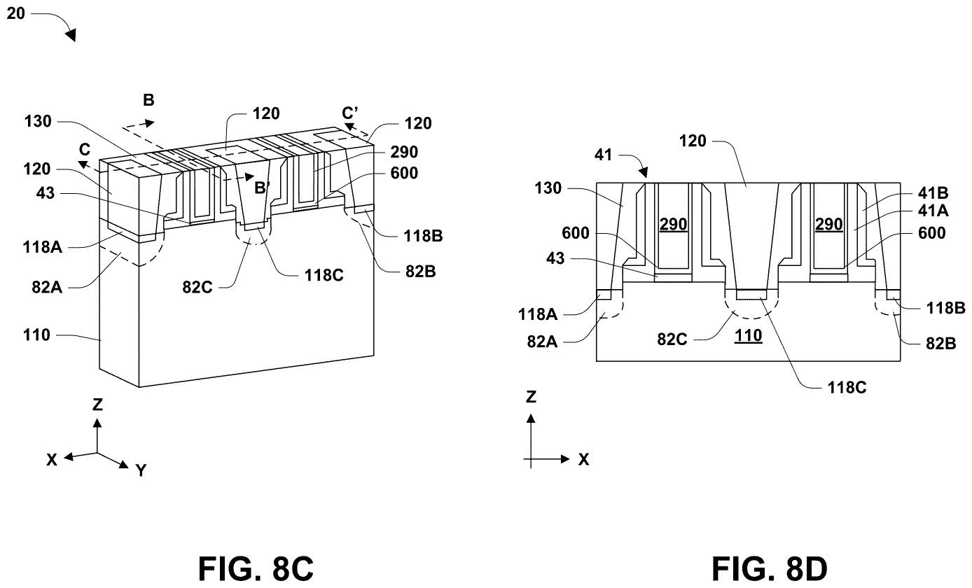

Following RPO formation, salicide (self-aligned silicide) formation can be performed. Formation of silicide layers 118A, 118B, 118C and optionally gate silicide layers 128, which can be self-aligned silicide or “salicide,” can reduce sheet resistance of source/drain regions 82A, 82B, 82C and gate lines 45 by forming a low-resistance metal silicide layer (e.g., NiSi, TiSi₂, or CoSi₂) on exposed silicon or polysilicon surfaces. This improves contact performance and signal propagation. In some embodiments, the silicide layers 118A, 118B, 118C and the gate silicide layers 128 are or include one or more of nickel, cobalt, titanium, tantalum, platinum, tungsten, other noble metals, other refractory metals, rare earth metals or their alloys. For example, the silicide layers 118 and the gate silicide layers 128 may be TiSi, TiNiSi, NiSi, WSi, CoSi, MoSi, RuSi, or the like. In some embodiments, the silicide layers 118A, 118B, 118C are formed after forming source/drain contact openings 59 and gate contact openings in an ILD layer 130 (see FIGS. 8A-8D, for example) and prior to forming source/drain contacts 120 and gate contacts 124C.

Formation of the silicide layers 118A, 118B, 118C and the gate silicide layers 128 can include surface preparation, such as cleaning the wafer on which the device 10 is formed, such as using dilute HF to remove native oxide from exposed source/drain regions 82A, 82B, 82C and gate lines 45, improving cleanliness of the silicon surfaces. Then, a thin layer of metal (e.g., nickel, titanium, or cobalt) can be deposited over the entire wafer on which the IC device 10 is located via physical vapor deposition (PVD), sputtering, or another suitable operation. A low-temperature anneal (e.g., 400° C. to 600° C. for NiSi) can be performed to react the metal with exposed silicon/polysilicon, forming a silicide layer in source/drain regions 82A, 82B, 82C and gate lines 45. The RPO can prevent silicide formation in protected areas. Then, unreacted metal (e.g., on RPO, spacers, or other dielectric surfaces) can be removed via a wet etch that includes, for example, a mixture of H₂SO₄ and H₂O₂ for nickel or another suitable mixture for titanium, cobalt or the like. Then, a higher-temperature anneal (e.g., 700° C. to 800° C. for NiSi) may be performed to stabilize the silicide phase, reducing its resistivity.

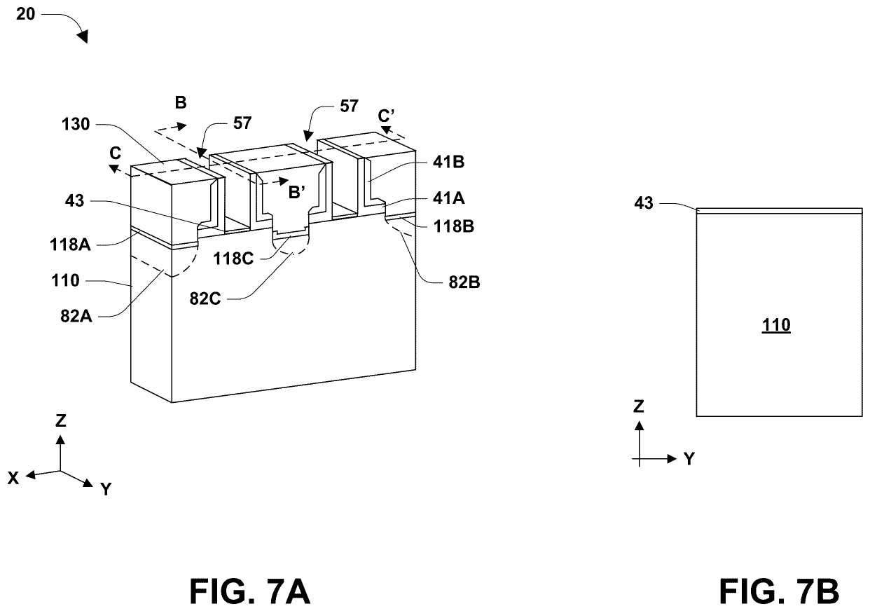

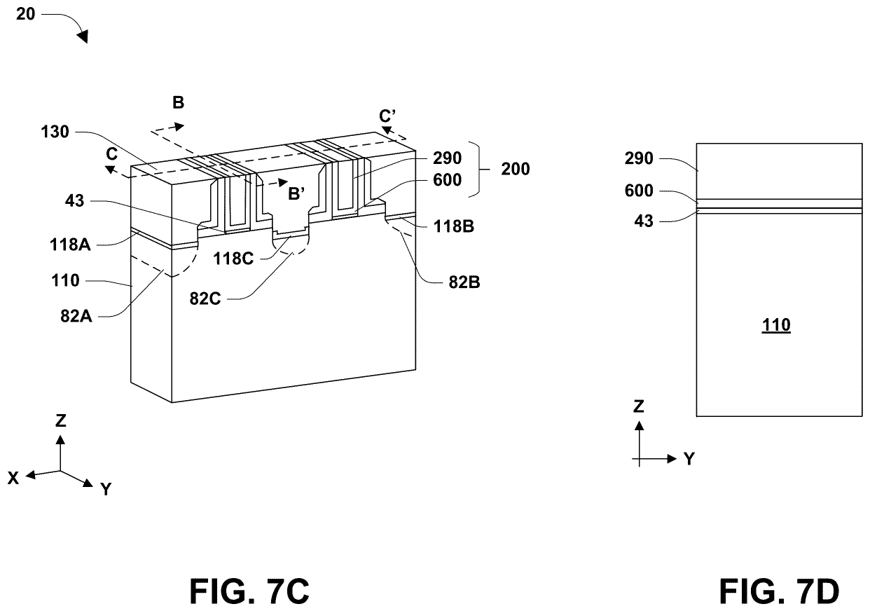

In FIGS. 7A-7D, following formation of the silicide layers 118A, 118B, 118C, the gate lines 45 are optionally replaced to form high-k metal gate (HKMG) structures 200 or simply “gate structures 200.”

In FIGS. 7A and 7B, the gate lines 45 are removed by a suitable removal process. Removal of the gate lines 45 can follow: (1) formation of the gate lines 45 and sidewall spacers 41, (2) implantation and annealing of source/drain regions 82A, 82B, 82C, (3) formation of the ILD layer 130 and (4) planarization (e.g., via chemical mechanical polishing, CMP) that exposes tops of the gate lines 45. The removal process can include an etching process that forms trenches 57 by removing the gate lines 45. The etching process can include a highly selective wet or dry etch that removes polysilicon of the gate lines 45. In some embodiments, the etching process includes a wet etch, such as using tetramethylammonium hydroxide (TMAH) or ammonium hydroxide (NH₄OH)-based solutions, which etch polysilicon of the gate lines 45 selectively over materials of the ILD layer 130 and the sidewall spacers 41. In some embodiments, the etching process includes a dry etch, such as a reactive ion etching (RIE) with chlorine-based (Cl₂) or fluorine-based (SF₆) precursors that are selected for high selectivity to polysilicon of the gate lines 45. The etching process can stop at the gate dielectric 43. As a result, the trenches 57 are formed between walls of the sidewall spacers 41, with the channel region (e.g., the substrate 110) protected by the gate dielectric 43 at the bottom. A post-etch clean (e.g., using dilute HF or piranha solution) can remove residues and prepare the trenches 57 for subsequent depositions.

In some embodiments, the gate dielectric 43 is optionally removed prior to HKMG formation. For example, the gate dielectric 43 may be a thin SiO₂ layer at the bottom of the trench 57, which can be removed by a dilute HF (hydrofluoric acid) etch, exposing the substrate 110. Then, a thin interfacial layer (IL), which can be SiO₂, SiON, or another suitable material, is grown or deposited to improve interface quality between the channels 22 and the high-k dielectric layer 600 that is deposited in a subsequent operation. The IL can be formed via controlled oxidation in an O₂ ambient to grow a thin SiO₂ layer, such as by using ozone or H₂O₂ to form a uniform IL. The IL can reduce interface traps and improve mobility.

Following formation of the trenches 57 and optional removal of the gate dielectric 43, a high-k dielectric layer 600 is formed that is beneficial to reduce current leakage and increase capacitance. In some embodiments, the dielectric layer 600 includes one or more high-k materials, which can be or include a hafnium-based dielectric (e.g., HfO₂, HfSiO₄), a zirconium-based dielectric (e.g., ZrO₂), or another suitable dielectric. The high-k dielectric layer 600 can be formed by a deposition process that includes atomic layer deposition (ALD), CVD or the like. Thickness of the high-k dielectric layer 600 can be in a range of about 1 nm to about 3 nm, or another suitable thickness. Following deposition of the high-k dielectric layer 600, a low-temperature anneal (e.g., 400-600° C. in N₂ or O₂) may be performed to densify the high-k dielectric layer 600 and reduce defects thereof. The high-k dielectric layer 600 can be positioned on the optional gate dielectric layer 43 or the underlying substrate 110 and on sidewalls of the sidewall spacers 41.

Following formation of the high-k dielectric layer 600 in the trenches 57, a metal layer 290 is formed in the trenches 57 on the high-k dielectric layer 600. In some embodiments, different metals may be selected for NMOS and PMOS transistors to achieve appropriate work functions. For example, in NMOS devices, the metal layer 290 may be or include one or more metals having work function close to a silicon conduction band (~4.1-4.3 eV), such as TiAl, TaN, or TiN with Al doping. In another example, in PMOS devices, the metal layer 290 may be or include one or more metals having work function close to a silicon valence band (~5.0-5.2 eV), such as TiN, TaN, or Mo. In some embodiments, the metal layer 290 includes a stack of multiple layers that are beneficial to select the work function and improve compatibility with the high-k dielectric layer 600. In some embodiments, the metal layer 290 is formed by one or more deposition processes that can include ALD or PVD. In some embodiments, the work function metal is not formed.

Following optional formation of work function metal layer(s), formation of the metal layer 290 can include formation of a low-resistance fill metal that can be or include one or more of tungsten (W), aluminum (Al), cobalt (Co) or the like, which can be beneficial for low resistivity and good fill properties. Formation of the metal layer 290 can include CVD, PVD, ALD, or the like. In some embodiments, an optional barrier or liner layer (e.g., TiN or TaN at 1-2 nm) may be deposited prior to depositing the fill metal to prevent diffusion and improve adhesion thereof. It should be understood that “fill” includes the meanings of partially fill and entirely fill.

Following formation of the metal layer 290, a planarization, such as a CMP can be performed that removes excess metal and high-k materials of the metal layer 290 and the high-k dielectric layer 600 to isolate the gate structures 200 and planarize the upper surfaces thereof. The planarization can stop at the upper surface of the ILD layer 130, leaving the HKMG stacks of the gate structures 200 within the trenches 57 between the walls of the sidewall spacers 41.

In FIGS. 8A-8D, source/drain contacts 120 are formed on the source/drain regions 82A, 82B, 82C.

In FIGS. 8A and 8B, source/drain openings 59 are formed in the ILD layer 130 that expose the silicide regions 118A, 118B, 118C on the source/drain regions 82A, 82B, 82C. Following formation of the ILD layer 130 and replacement gate structures 200, source/drain openings 59 are formed in the ILD layer 130. The source/drain openings 59 can be formed by an etching process, which can be or include a reactive ion etching (RIE) process that uses a fluorocarbon-based chemistry (e.g., CF₄, CHF₃, or C₄F₈) to etch through the ILD layer 130 to expose the silicide regions 118A, 118B, 118C on the source/drain regions 82A, 82B, 82C. The etch can be anisotropic, which can result in vertical sidewalls of the ILD layer 130 exposed by the source/drain openings 59. Following the RIE process, a wet clean (e.g., dilute HF) or plasma strip can be performed to remove polymer residues and native oxide from surfaces of the silicide regions 118A, 118B, 118C to improve (e.g., reduce) contact resistance. In some embodiments, the silicide layers 118A, 118B, 118C are formed after forming the source/drain contact openings 59 and gate contact openings in an ILD layer 130 (see FIGS. 8A-8D, for example) and prior to forming source/drain contacts 120 and gate contacts 124C.

In FIGS. 8C and 8D, an optional barrier layer, which can include a thin Ti/TiN stack, can be deposited into the source/drain openings 59 to improve adhesion, reduce contact resistance, and reduce diffusion of a fill metal of the source/drain contacts 120. The Ti layer can be deposited via physical vapor deposition (PVD), ionized PVD or chemical vapor deposition (CVD). Then, the TiN layer can be deposited via PVD, CVD, or ALD. A fill metal layer that can include tungsten (W) or another suitable metal can then be deposited via CVD, such as by using a WF₆ precursor to fill the source/drain openings 59. In some embodiments, forming the fill metal layer can include a nucleation operation, in which a thin W seed layer (e.g., via silane or B₂H₆ reduction) is deposited to initiate uniform growth. Then, WF₆-based CVD can be performed to fill the source/drain openings 59. A planarization, such as a CMP, can be performed that removes excess W and barrier materials and planarizes a wafer surface to isolate the source/drain contacts 120 and prepare for formation of interconnects of the interconnect structure 140 described with reference to FIGS. 1A-1D.

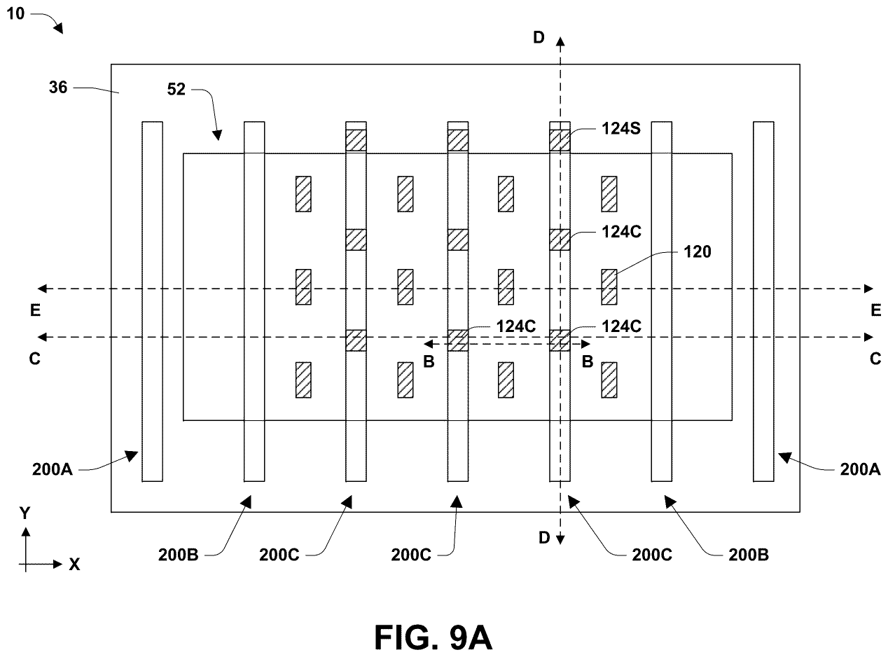

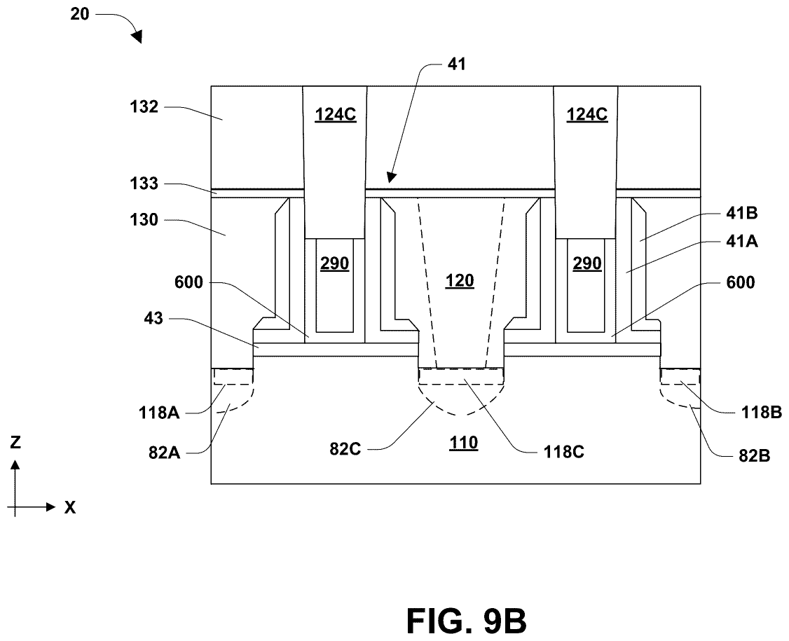

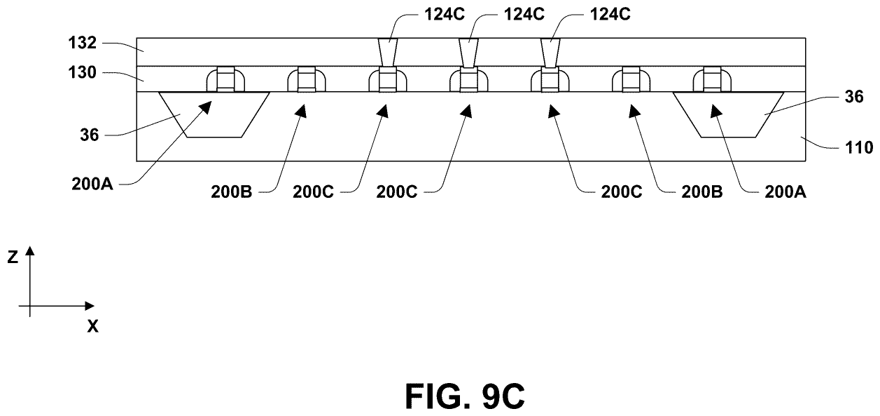

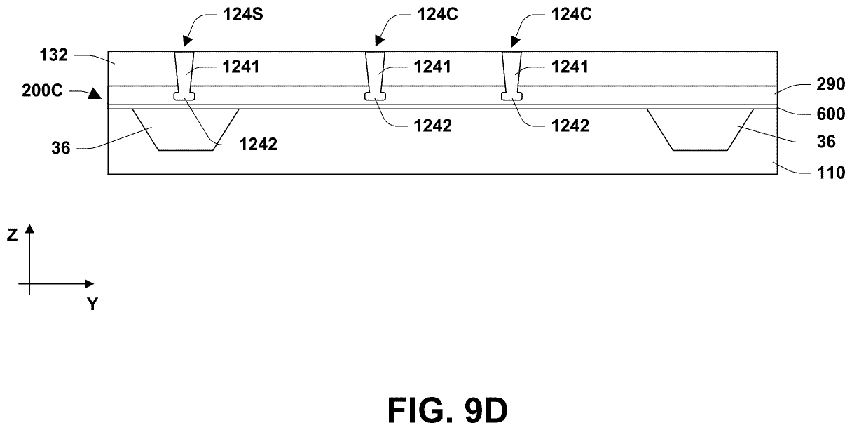

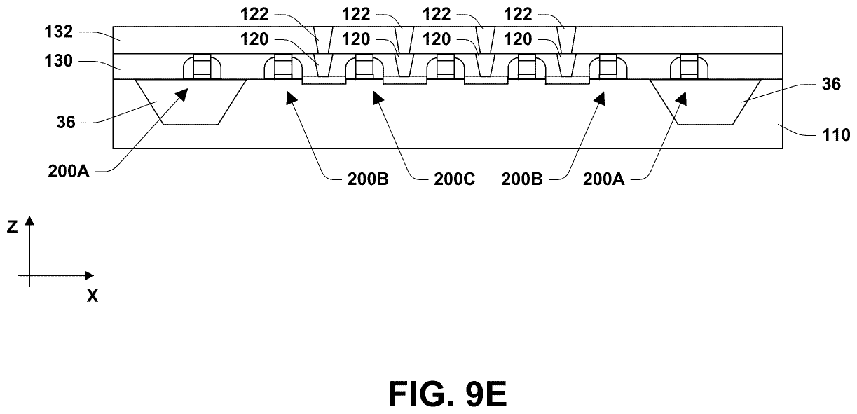

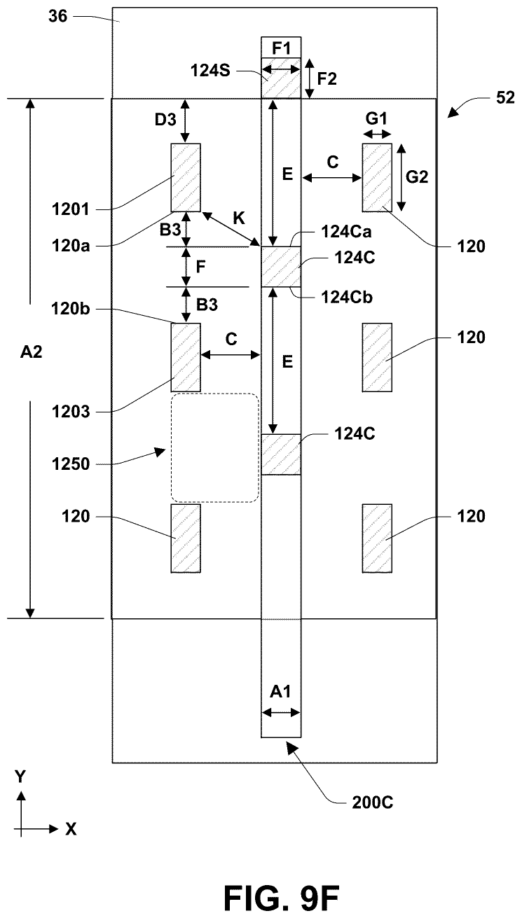

FIGS. 9A-9F illustrate diagrammatic plan and cross-sectional views of the IC device 10, in accordance with some embodiments. FIG. 9A illustrates a plan view of the IC device 10. FIG. 9B illustrates a cross-sectional side view of the IC device 10 along line B-B of FIG. 9A. FIG. 9C illustrates a cross-sectional side view of the IC device 10 along line C-C of FIG. 9A. FIG. 9D illustrates a cross-sectional side view of the IC device 10 along line D-D of FIG. 9A. FIG. 9E illustrates a cross-sectional side view of the IC device 10 along line E-E of FIG. 9A.

In FIG. 9A, following formation of the source/drain contacts 120 on the source/drains 82, first gate contacts 124S and second gate contacts 124C are formed on the gate structures 2000. The first gate contacts 124S are formed on the gate structures 2000 and overlapping the isolation structure 36. The second gate contacts 124C are formed on the gate structures 2000 and overlapping the active area 52.

FIG. 9B illustrates the second gate contacts 124C on two of the gate structures 2000, in accordance with various embodiments. In some embodiments, prior to forming the second gate contacts 124C, an etch stop layer (ESL) 133 is formed on the ILD layer 130, the spacers 41 and the metal layers 290. Then, a second ILD layer 132 is formed on the ESL 133. The ESL 133 can be or include a dielectric layer, such as a SiN layer or other appropriate dielectric layer. The second ILD layer 132 can be or include another dielectric layer that can be or include a low-k dielectric, silicon dioxide, carbon doped silicon dioxide, silicon oxynitride, borosilicate glass (BSG), phosphoric silicate glass (PSG), borophosphosilicate glass (BPSG), fluorinated silicate glass (FSG), a porous dielectric material, or the like. In some embodiments, the second ILD layer 132 can be formed by via a high-density plasma (HDP) CVD process or another suitable process. For example, the second ILD layer 132 can be HDP PSG.

Then, gate contact openings can be formed that extend through the second ILD layer 132 and the ESL 133 and partially into the metal layer 290 of the gate structures 2000 and source/drain via openings can be formed over the source/drain contacts 120, corresponding to act 1208 of FIG. 12. The gate contact openings can include openings that are formed that land on the gate structures 2000 and overlap the isolation structure 36 and openings that land on the gate structures 2000 and overlap the active area 52. Formation of the gate contact openings can include a suitable etching operation, such as a dry etch that is anisotropic and removes material of the second ILD layer 132 and can extend the gate contact openings into the metal layer 290 by removing material of the metal layer 290. Following the etching operation, a wet clean may be performed. As a result of performing the wet clean, lateral etching may occur at the bottom of the gate contact openings that expands width of the gate contact openings along the Y-axis direction. Namely, performing the wet clean after dry etch that forms contact openings may cause lateral etching at the bottom of the gate contact openings. For example, the wet clean may be an anisotropic etch that removes material of the metal layer 290 and the high-k dielectric layer 600 along the Y-axis direction, which is not constrained by the sidewall spacers 41. This can result in lower portions 1242 of the first gate contacts 124S and the second gate contacts 124C having width that exceeds width of upper portions 1241 of the first gate contacts 124S and the second gate contacts 124C at an interface of the upper portions 1241 and the lower portions 1242, as illustrated in the view of FIG. 9D. Etching of the gate contact openings may be constrained along the X-axis direction by the sidewall spacers 41, which can act as a lateral etch stop when removing material of the metal layer 290.

Following formation of the gate contact openings, the second gate contacts 124C (and the first gate contacts 124S) are formed in the gate contact openings and source/drain vias 122 (see FIG. 9E) are formed in the source/drain via openings, corresponding to acts 1210 and 1212 of FIG. 12. Acts 1210 and 1212 can be performed simultaneously, in some embodiments. Formation of the first gate contacts 124S and the second gate contacts 124C can include forming a liner layer and a metal fill layer, which can be similar in many respects to formation of the source/drain contacts 120 described with reference to FIGS. 8A-8D. In some embodiments, the first gate contacts 124S and the second gate contacts 124C can be or include one or more layers of Ti, TiN, tungsten, aluminum, copper, cobalt or the like. The layers may be formed by a suitable deposition process, such as a PVD, CVD, or ALD. The first gate contacts 124S and the second gate contacts 124C can inherit shape of the gate contact openings. As a result, the first gate contacts 124S and the second gate contacts 124C can be in contact with (e.g., direct contact with) the sidewall spacers 41 along the X-axis direction, as depicted in FIG. 9B.

FIG. 9C illustrates the second gate contacts 124C on the gate structures 2000 whereas the first dummy gate structures 200B and the second dummy gate structures 200A are free of the second gate contacts 124C. In some embodiments, the gate structures 2000 include the gate lines 45 instead of the metal layer 290, as shown.

FIG. 9D illustrates the second gate contacts 124C and one of the first gate contacts 124S on and in the metal layer 290 of one of the gate structures 2000. As described with reference to FIG. 9A, the gate contact openings can extend into the metal layer 290, can stop on the sidewall spacers 41 along the X-axis direction and can extend laterally along the Y-axis direction. The first gate contacts 124S and the second gate contacts 124C can inherit shape of the gate contact openings. For example, the first gate contacts 124S and the second gate contacts 124C can each have an upper portion 1241 that extends through the second ILD layer 132 and into the metal layer 290. The first gate contacts 124S and the second gate contacts 124C can each have a lower portion 1242 that is embedded in the metal layer 290 and extends laterally along the Y-axis direction.

FIG. 9E illustrates formation of source/drain vias 122 on each of the respective source/drain contacts 120. Each of the source/drain vias 122 can extend through the second ILD layer 132 and land on the respective source/drain contact 120. Formation of the source/drain vias 122 can be similar in most respect to that of the source/drain contacts 120 and/or that of the first gate contacts 124S and the second gate contacts 124C.

Following formation of the source/drain vias 122, the first gate contacts 124S and the second gate contacts 124C, which may be formed in the same operation(s), the interconnect structure 140 can be formed thereover.

FIG. 9F illustrates a detailed plan view of an area of the IC device 10, in accordance with some embodiments.

In FIG. 9F, each of the first gate contacts 124S and the second gate contacts 124C has first dimension (e.g., width) F1 along the X-axis direction and second dimension (e.g., length) F2 along the Y-axis direction. In some embodiments, the first dimension F1 is substantially equal to a length A1 of the gate structure 2000 on which the first gate contacts 124S and the second gate contacts 124C are positioned. In some embodiments, the first dimension F1 is different than (e.g., less than) the length A1. In some embodiments, the length A1 is in a range of about 20 nanometers to about 0.18 micrometers. In some embodiments, the first dimension F1 and the second dimension F2 are each in a range of about 20 nanometers to about 0.1 micrometers. In some embodiments, the first dimension F1 and the second dimension F2 are substantially equal to each other, such that the first gate contacts 124S and the second gate contacts 124C have square profile in the plan view. In some embodiments, the first gate contacts 124S and the second gate contacts 124C have a profile in the plan view that is another shape instead of square, such as a rectangle, circle, ellipse, or the like. In some embodiments, separation E along the Y-axis direction between immediately adjacent pairs of the first gate contacts 124S and/or the second gate contacts 124C is in a range of about 0.3 micrometers to about 30 micrometers, and generally exceeds about 0.3 micrometers.

Each of the source/drain contacts 120 has first dimension (e.g., width) G1 along the X-axis direction and second dimension (e.g., length) G2 along the Y-axis direction. In some embodiments, the second dimension G2 exceeds the first dimension G1, such that the source/drain contacts 120 have rectangular profile in the plan view. In some embodiments, the first dimension G1 and the second dimension G2 are each in a range of about 20 nanometers to about 0.1 micrometers. Each of the source/drain contacts 120 may be separated from the immediately adjacent gate structure 2000 along the X-axis direction by a dimension C. In some embodiments, the dimension C exceeds about half the first dimension G1. For example, the first dimension G1 (e.g., width) of the source/drain contact 120 may be about 20 nanometers and the source/drain contact 120 may be separated from the gate structure 2000 by at least 10 nanometers. In another example, the source/drain contact 120 may have the first dimension G1 of about 100 nanometers and may be separated from the gate structure 2000 by at least 50 nanometers.

Separation distance K between each of the source/drain contacts 120 and the closest second gate contact(s) 124C thereto may be selected based on the dimension C and a dimension B3. In some embodiments, the dimension B3 is separation between the source/drain contact 120 and the second gate contact 124C along the Y-axis direction. For example, the second gate contact 124C can have dimension F (e.g., length) along the Y-axis direction between a first sidewall 124Ca thereof and a second sidewall 124Cb thereof. The dimension F can be the same as the second dimension F2, in some embodiments. The dimension B3 can be a distance between a sidewall 120a of a first source/drain contact 1201 and a projection of the first sidewall 124Ca and/or between a sidewall 120b of a second source/drain contact 1203 and a projection of the second sidewall 124Cb. The separation distance K can be calculated using the following equation:

$$\\ K = \sqrt{B {3}^{2} + {C}^{2}} .$$

In some embodiments, the separation distance K exceeds a smallest dimension of the first dimension F1, the second dimension F2, the first dimension G1 and the second dimension G2.

An example is provided to understand the separation distance K. In the example, the first dimension G1 (e.g., width) of the source/drain contacts 120 may be the smallest dimension and may be about 20 nanometers. As such, the dimension C that separates the source/drain contacts 120 from the gate structure 2000 may be about 10 nanometers. However, because the first dimension G1, which is the smallest dimension, is about 20 nanometers, the separation distance K also exceeds about 20 nanometers. Namely, the separation distance K exceeds the dimension C. As a result, a keepout region 1250 depicted by a dashed line is present over the active region 52 immediately adjacent to the second gate contact 124C. Namely, the dimension B3 by which the source/drain contact 120 is offset along the Y-axis direction from the second gate contact 124C exceeds zero to ensure that sufficient distance (e.g., equal to or exceeding the separation distance K) is present between the source/drain contact 120 and the nearest second gate contact 124C. As such, when the smallest dimension of the first dimension F1, the second dimension F2, the first dimension G1 and the second dimension G2 exceeds the dimension C, the source/drain contact 120 does not overlap the second gate contact 124C and is offset therefrom along the Y-axis direction.

FIG. 9F also depicts a dimension D3, which is a separation between the source/drain contact 120 and the isolation structure 36. In some embodiments, the dimension D3 is in a range of about 20 nanometers to about 0.1 micrometers.

FIG. 9F also depicts a dimension A2, which is a width of the active area 52 along the Y-axis direction. In some embodiments, the dimension A2 is in a range of about 0.5 micrometers to about 12 micrometers.

FIGS. 10A-10F illustrate plan and cross-sectional side views of the IC device 10 in accordance with various embodiments. The embodiments described with reference to FIGS. 10A-10F can be combined with the embodiments described with reference to FIGS. 1A-9F.

In FIG. 10A, the IC device 10 includes the active gate structures 2000 and is free of the first dummy gate structures 200B and/or the second dummy gate structures 200A. As such, at least two of the active gate structures 2000 can be immediately adjacent to opposing sides of the isolation structure 36 without additional gate structures (e.g., the first dummy gate structures 200B) therebetween. The isolation structure 36 immediately laterally surrounding the gate structures 2000 and the active area 52 can be free of gate structures (e.g., the second dummy gate structures 200A) other than extensions of the gate structures 2000 that overlap the isolation structure 36.

In FIG. 10B, the IC device 10 includes the first gate contacts 124S, the second gate contacts 124C and the source/drain contacts 120 that have elliptical or oval shape instead of square shape or rectangular shape in the plan view. The embodiment of FIG. 10B can be combined with the embodiment of FIG. 10A to include the elliptically-shaped first gate contacts 124S, second gate contacts 124C and source/drain contacts 120 and omit the first dummy gate structures 200B and the second dummy gate structures 200A. In some embodiments, the first gate contacts 124S and the second gate contacts 124C are elongated along the X-axis direction and the source/drain contacts 120 are elongated along the Y-axis direction. The second gate contacts 124C can have width in the X-axis direction that exceeds length of the gate structures 2000 in the X-axis direction, such that the second gate contacts 124C can overlap and extend beyond opposing sidewalls of the respective gate structure 2000 they are positioned over. The second gate contacts 124C having the enlarged elliptical shape in the plan view as illustrated in FIG. 10B can reduce the gate resistance, which can increase fₘₐₓ of the IC device 10. The elliptical shape can also increase area of the first gate contacts 124S, the second gate contacts 124C and the source/drain contacts 120 while maintaining the separation distance K described with reference to FIG. 9F.

In FIG. 10C, the IC device 10 includes the first gate contacts 124S, the second gate contacts 124C and the source/drain contacts 120 that have elliptical or oval shape instead of square shape or rectangular shape in the plan view. The embodiment of FIG. 10C can be combined with the embodiment of FIG. 10A to include the elliptically-shaped first gate contacts 124S, second gate contacts 124C and source/drain contacts 120 and omit the first dummy gate structures 200B and the second dummy gate structures 200A. In some embodiments, the first gate contacts 124S, the second gate contacts 124C and the source/drain contacts 120 are elongated along the Y-axis direction.

In FIG. 10D, the IC device 10 includes the first gate contacts 124S, the second gate contacts 124C and the source/drain contacts 120 that have elliptical or oval shape instead of square shape or rectangular shape in the plan view. The embodiment of FIG. 10D can be combined with the embodiment of FIG. 10A to include the elliptically-shaped first gate contacts 124S, second gate contacts 124C and source/drain contacts 120 and omit the first dummy gate structures 200B and the second dummy gate structures 200A. In some embodiments, the first gate contacts 124S are elongated along the Y-axis direction and partially overlap the respective gate structures 2000. For example, the first gate contacts 124S may have enlarged size in the X-axis direction and the Y-axis direction, and a portion of each of the first gate contacts 124S may overlap the active area 52. Increasing contact area of the first gate contacts 124S can reduce the gate resistance, which can increase fₘₐₓ of the IC device 10.

FIG. 10E illustrates a detailed cross-sectional view of a second gate contact 124C along line E-E of FIG. 10A. FIG. 10F illustrates a detailed cross-sectional view of a second gate contact 124C along line F-F of FIG. 10B.

In FIG. 10E, the second gate contact 124C includes the first portion 1241 that is above the sidewall spacers 41 and the second portion 1242 that is below the first portion 1241. In some embodiments, the first portion 1241 does not extend laterally beyond the sidewall spacers 41 along the X-axis direction. The second portion 1242 may extend from one of the sidewall spacers 41 to another of the sidewall spacers 41. Prior to formation of the second gate contact 124C, the metal layer 290 of the replacement gate structure 2000 can extend from the dielectric layer 600 to the upper surface of the sidewall spacers 41, which is depicted by a first height H1 and a dashed line in FIG. 10E. Following formation of the second gate contact 124C, due to some material of the metal layer 290 being removed during etching of the opening in which the second gate contact 124C is formed, the metal layer 290 may have second height H2 that is less than the first height H1. In some embodiments, a ratio of the second height H2 over the first height H1 is in a range of about 5% to about 90%. Namely, an amount of the metal layer 290 removed may be in a range of about 10% to about 95% of the first height H1. In some embodiments, amount of the metal layer 290 removed when forming the first gate contacts 124S that are positioned over the isolation region 36 is in a range of about 5% to 90% of the first height H1. In some embodiments, remaining thickness of the metal layer 290 under the first gate contact 124S and the second gate contact 124C is in a range of about 0 nanometers to about 300 nanometers. In some embodiments, the metal layer 290 overlapping the first gate contact 124S or the second gate contact 124C is completely removed, such that the first gate contact 124S or the second gate contact 124C is in direct contact with the dielectric layer 600.

Although the embodiments described with reference to FIG. 10E include the metal layer 290, in some embodiments, the dielectric layer 600 and the metal layer 290 are not present and instead the gate line 45 is present between the first gate contacts 124S, the second gate contacts 124C and the substrate 110 and/or the gate dielectric layer 43.

FIG. 10F illustrates the second gate contact 124C that has the elliptical-shaped profile in the plan view as described with reference to FIG. 10B. In some embodiments, the second gate contact 124C has elliptical shape in the plan view and the sidewall spacers 41 have second width W2 that exceeds first width W1 of the sidewall spacers 41 associated with the second gate contact 124C that has the square or rectangular shape in the plan view.

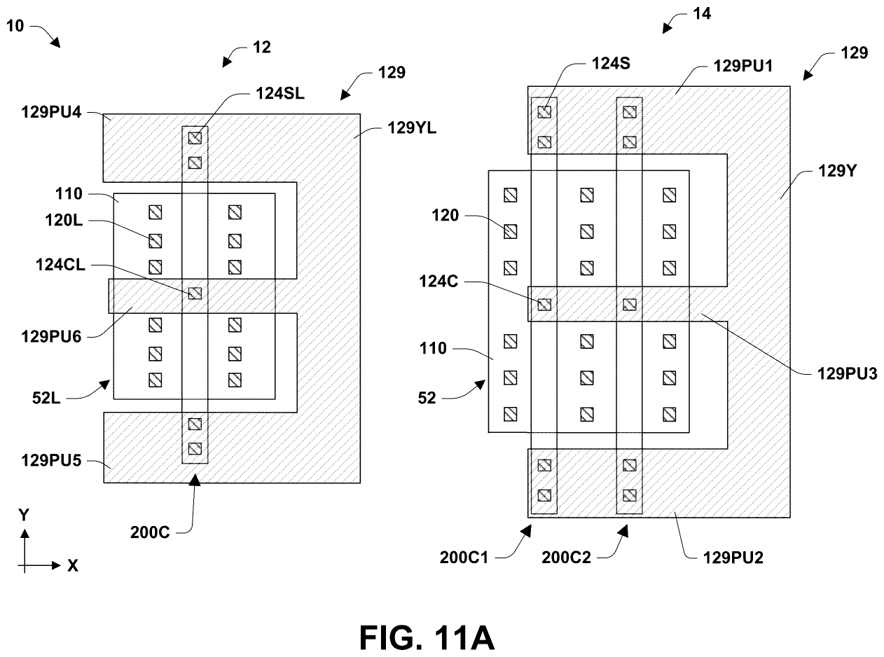

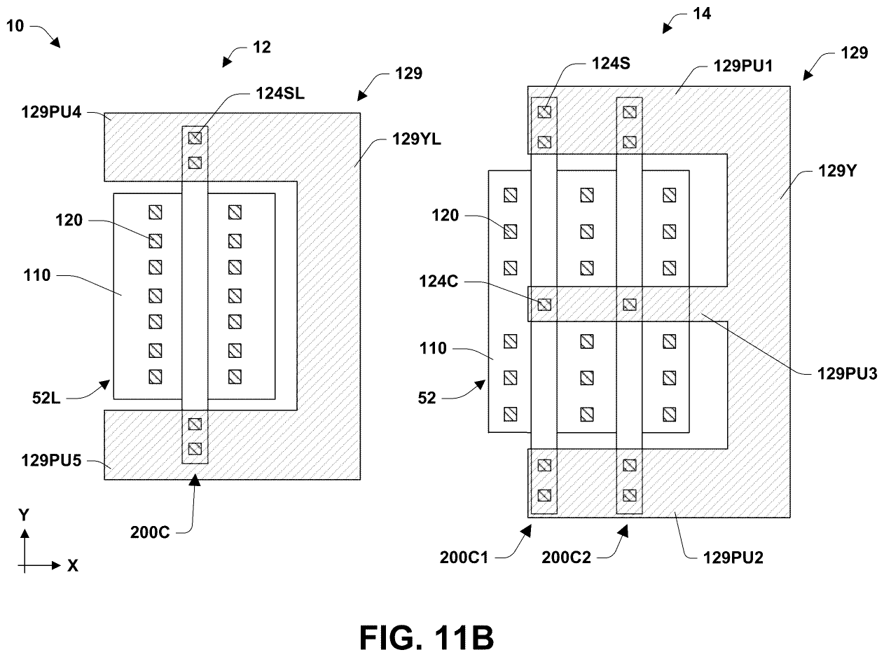

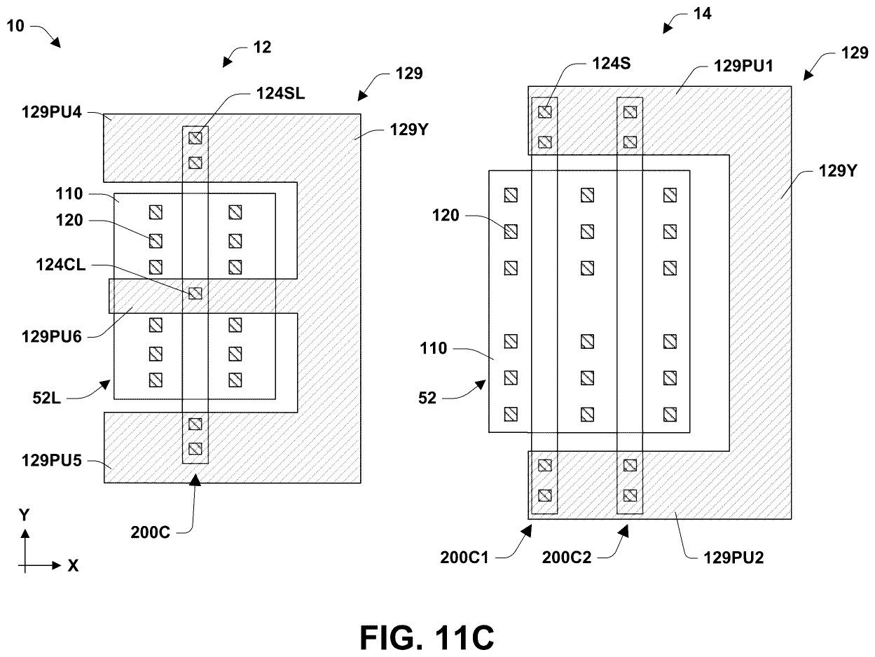

FIGS. 11A-11C illustrate plan views of the IC device 10, in accordance with some embodiments.

In FIG. 11A, in some embodiments, the IC device 10 includes a logic device 12 and an RF device 14. The IC device 10 can comprise the substrate 110, the isolation structure 36 positioned in the substrate 110 (not separately labeled in FIG. 11A) and one or more of the active areas 52 defined in the substrate 110 that are laterally surrounded by the isolation structure(s) 36. In some embodiments, the RF device 14 is operable to receive and/or transmit first electrical signals at a first operating frequency, which may be in a range of about 30 GHz to about 200 GHz, such as would be associated with fₘₐₓ of the RF device 14 that is in a range of about 300 GHz to about 400 GHz. In some embodiments, the logic device 12 is operable to receive and/or transmit second electrical signals at a second operating frequency, which may be in a range of about 1 GHz to about 10 GHz.

The RF device 14 can include the first gate structure 200C1 (or the first gate line 45) that extends in a first direction (e.g., the Y-axis direction), is positioned on the substrate 110 and overlaps the active area 52 and the isolation structure 36. The RF device 14 can include the second gate structure 200C2 (or second gate line 45) immediately adjacent the first gate structure 200C1 or the first gate line 45 along a second direction (e.g., the X-axis direction) that is transverse the first direction. The second gate structure 200C2 or second gate line 45 extends in the first direction, is positioned on the substrate 110 and overlaps the active area 52 and the isolation structure 36.

The RF device 14 can include one or more first gate contacts 124S positioned on the first gate structure 200C1 or first gate line 45 and overlapping the isolation structure 36. The RF device 14 can include one or more second gate contacts 124C positioned on the first gate structure 200C1 or first gate line 45 and overlapping the active area 52. The RF device 14 can include one or more third gate contacts 124S positioned on the second gate structure 200C2 or second gate line 45 and overlapping the isolation structure 36. The RF device 14 can include one or more fourth gate contacts 124C positioned on the second gate structure 200C2 or the second gate line 45 and overlapping the active area 52. The RF device 14 includes source/drain contacts 120 on the active area 52.

The RF device 14 includes portions of a metal layer 129, which can be a first metal (M1) layer that is immediately adjacent (above) a bottom metal layer (e.g., M0) in which the first gate contacts 124S, the second gate contacts 124C and the source/drain vias 122 are positioned. In some embodiments, the metal layer 129 is a second metal layer (M2), third metal layer (M3) or other metal layer that is above but not immediately adjacent to the bottom metal layer, and has other intervening metal layers (e.g., M1, M2, M3, etc.) therebetween. The RF device 14 includes a first portion 129Y of the metal layer 129 that extends along the first direction (e.g., the Y-axis direction) and overlaps the isolation structure 36. The RF device 14 includes one or more second portions 129PU1, 129PU2 of the metal layer 129, which can be first pick-up portions, that extend from the first portion 129Y along the second direction (e.g., the X-axis direction). The second portions 129PU1, 129PU2 overlap the first gate contact(s) 124S on the first gate structure 200C1 and the third gate contact(s) 124S on the second gate structure 200C2. The RF device 14 includes a third portion 129PU3 of the metal layer 129, which can be a second pick-up portion, that extends from the first portion 129Y along the second direction and overlaps the second gate contact(s) 129C on the first gate structure 200C1 and the fourth gate contact(s) 129C on the second gate structure 200C2. The third portion 129PU3 overlaps the active area 52 and may have a region thereof that overlaps the isolation structure 36.

The logic device 12 can be similar in many respects to the RF device 14. For example, the logic device 12 can include a second active area 52L and a gate structure 2000 that extends across the second active area 52L. The logic device 12 can include one or more fifth gate contacts 124SL on the gate structure 2000 that overlap the isolation structure 36 and one or more sixth gate contacts 124CL on the gate structure 2000 that overlap the active area 52L. The logic device 12 includes a fourth portion 129YL of the metal layer 129 that extends in the first direction (e.g., the Y-axis direction). The logic device 12 includes one or more fifth portions 129PU4, 129PU5 of the metal layer 129, which can be third pick-up portions, that extend from the fourth portion 129YL along the second direction (e.g., the X-axis direction). The fifth portions 129PU4, 129PU5 overlap the fifth gate contact(s) 124SL on the gate structure 2000 and overlapping the isolation structure 36. The logic device 12 includes a sixth portion 129PU6 of the metal layer 129 that extends from the fourth portion 129YL along the second direction and overlaps the sixth gate contact(s) 129CL on the gate structure 2000. The sixth portion 129PU6 overlaps the active area 52 and may have a region thereof that overlaps the isolation structure 36. The logic device 12 includes source/drain contacts 120 on the second active area 52L.

FIG. 11B illustrates the IC device 10 in which the gate structure 2000 of the logic device 12 is free of gate contacts (e.g., the sixth gate contact(s) 124CL) and the sixth portion 129PU6 is omitted.

FIG. 11C illustrates the IC device 10 in which the first gate structure 200C1 and/or the second gate structure 200C2 of the RF device 14 is free of gate contacts (e.g., the second gate contact(s) 124C and/or the fourth gate contact(s) 124C) and the third portion 129PU3 is omitted.

One or more embodiments involve a computer-readable medium comprising processor-executable instructions configured to implement one or more of the techniques presented herein. An exemplary computer-readable medium is illustrated in FIG. 13, wherein the embodiment 90 comprises a computer-readable medium 908 (e.g., a CD-R, DVD-R, flash drive, a platter of a hard disk drive, etc.), on which is encoded computer-readable data 906. This computer-readable data 906 in turn comprises a set of processor-executable computer instructions 904 configured to implement one or more of the principles set forth herein when executed by a processor. In some embodiments 90, the processor-executable computer instructions 904 are configured to implement a method 902, such as at least some of the aforementioned method(s) when executed by a processor. In some embodiments, the processor-executable computer instructions 904 are configured to implement a system, such as at least some of the one or more aforementioned system(s) when executed by a processor. Many such computer-readable media may be devised by those of ordinary skill in the art that are configured to operate in accordance with the techniques presented herein.

In some embodiments, a device is provided. The device includes: a substrate; an isolation structure positioned in the substrate; an active area defined in the substrate, the active area being laterally surrounded by the isolation structure; a first gate line that extends in a first direction, the first gate line being positioned on the substrate and overlapping the active area and the isolation structure; a second gate line immediately adjacent the first gate line along a second direction transverse the first direction, the second gate line extending in the first direction, the second gate line being positioned on the substrate and overlapping the active area and the isolation structure; a first contact positioned on the first gate line and overlapping the isolation structure; a second contact positioned on the first gate line and overlapping the active area; a third contact positioned on the second gate line and overlapping the isolation structure; a fourth contact positioned on the second gate line and overlapping the active area; and a metal layer. The metal layer includes: a first portion that extends along the first direction, the first portion overlapping the isolation structure; a second portion that extends from the first portion along the second direction, the second portion overlapping the first contact and the third contact; and a third portion that extends from the first portion along the second direction, the third portion overlapping the second contact and the fourth contact.

In some embodiments, a device is provided. The device includes: a logic device and a radio-frequency device. The logic device includes: a first gate line overlapping a first active area of a substrate and overlapping an isolation structure adjacent the first active area; a first source/drain in the substrate immediately adjacent the first gate line; and a first contact on the first gate line and overlapping the isolation structure. The radio-frequency device includes: a second gate line overlapping a second active area of the substrate separated from the first active area by the isolation structure; a second source/drain in the substrate immediately adjacent the second gate line; a second contact on the second gate line and overlapping the isolation structure; and a third contact on the second gate line and overlapping the second active area.

In some embodiments, a method is provided. The method includes: forming a first active area of a substrate including forming an isolation structure in the substrate, the isolation structure being adjacent the first active area; forming a first gate line that extends along a first direction and overlaps the first active area and the isolation structure; forming a first source/drain adjacent the first gate line in the first active area; forming a first opening, a second opening and a third opening in a dielectric layer exposed by a mask layer, the first opening overlapping the first gate line and the isolation structure, the second opening overlapping the first gate line and the first active area, and the third opening overlapping the first source/drain; forming a first contact in the first opening and a third contact in the third opening; and reducing alternating current (AC) resistance of the first gate line by forming a second contact in the second opening.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A device, comprising:
a substrate;
an isolation structure positioned in the substrate;
an active area defined in the substrate, the active area being laterally surrounded by the isolation structure;
a first gate line that extends in a first direction, the first gate line being positioned on the substrate and overlapping the active area and the isolation structure;
a second gate line immediately adjacent the first gate line along a second direction transverse the first direction, the second gate line extending in the first direction, the second gate line being positioned on the substrate and overlapping the active area and the isolation structure;
a first contact positioned on the first gate line and overlapping the isolation structure; and
a second contact positioned on the first gate line and overlapping the active area.

2. The device of claim 1, comprising:
a first source/drain positioned between the first gate line and the second gate line on a first side of the first gate line;
a second source/drain positioned on a second side of the first gate line opposite the first side; and
a fifth contact positioned on the second source/drain, the fifth contact having a fifth width along the second direction and a fifth length along the first direction.

3. The device of claim 2, wherein:
the fifth contact is separated from the first gate line along the second direction by a first distance (C);
the fifth contact is offset from the second contact along the first direction by a second distance (B3);
the second contact has a second width along the second direction and a second length along the first direction; and
a shortest distance (K) between the fifth contact and the second contact is K=\sqrt{C²+B3²} and exceeds a minimum of the second width, the second length, the fifth width and the fifth length.

4. The device of claim 3, wherein the first distance between the fifth contact and the first gate line exceeds about 50% of the fifth width of the fifth contact positioned on the second source/drain.

5. The device of claim 1, comprising:
a sixth contact that is positioned on the first gate line and overlaps the isolation structure and the active area.

6. The device of claim 1, wherein the first gate line includes:
a gate dielectric layer; and
a metal layer on the gate dielectric layer;
wherein the second contact extends into the metal layer to a depth that is below an upper surface of the metal layer.

7. The device of claim 6, wherein the second contact has a bottom portion that extends laterally into the metal layer along the first direction.

8. The device of claim 1, further comprising:
a third contact positioned on the second gate line and overlapping the isolation structure;
a fourth contact positioned on the second gate line and overlapping the active area; and
a metal layer that includes:
a first portion that extends along the first direction, the first portion overlapping the isolation structure;
a second portion that extends from the first portion along the second direction, the second portion overlapping the first contact and the third contact; and
a third portion that extends from the first portion along the second direction, the third portion overlapping the second contact and the fourth contact.

9. The device of claim 1, wherein the second contact has elliptical shape elongated along the second direction and the second contact extends along the second direction beyond outer sidewalls of the first gate line.

10. The device of claim 1, comprising:
an inactive gate line adjacent the first gate line along the second direction, the first gate line being positioned between the inactive gate line and the second gate line.

11. A device comprising:
a first device including:
a first gate line overlapping a first active area of a substrate and overlapping an isolation structure adjacent the first active area;
a first source/drain in the substrate immediately adjacent the first gate line; and
a first contact on the first gate line and overlapping the isolation structure; and
a second device including:
a second gate line overlapping a second active area of the substrate separated from the first active area by the isolation structure;
a second source/drain in the substrate immediately adjacent the second gate line;
a second contact on the second gate line and overlapping the isolation structure; and
a third contact on the second gate line and overlapping the second active area.

12. The device of claim 11, wherein the first device includes:
a fourth contact on the first gate line and overlapping the first active area.

13. The device of claim 11, wherein the second device includes:
a plurality of source/drain contacts that are arranged in a row that extends parallel to the second gate line and is separated from the second gate line by a first distance, each of the plurality of source/drain contacts being separated from the third contact by a distance that exceeds: width of the respective source/drain contact, length of the respective source/drain contact, width of the second contact and length of the second contact.

14. The device of claim 11, comprising:
a first metal layer that is electrically coupled to and overlaps the first contact and defines an opening that fully overlaps the first active area; and
a second metal layer that is electrically coupled to the second contact and the third contact and has an extension portion that partially overlaps the second active area and fully overlaps the third contact.

15. The device of claim 14, wherein the second device includes:
a third gate line overlapping the second active area of the substrate;
a third source/drain in the substrate immediately adjacent the third gate line;
a fourth contact on the third gate line and overlapping the isolation structure; and
a fifth contact on the third gate line and overlapping the second active area;
wherein the extension portion of the second metal layer fully overlaps the fifth contact.

16. A method, comprising:
forming a first active area of a substrate including forming an isolation structure in the substrate, the isolation structure being adjacent the first active area;
forming a first gate line that extends along a first direction and overlaps the first active area and the isolation structure;
forming a first source/drain adjacent the first gate line in the first active area;
forming a first opening, a second opening and a third opening in a dielectric layer exposed by a mask layer, the first opening overlapping the first gate line and the isolation structure, the second opening overlapping the first gate line and the first active area, and the third opening overlapping the first source/drain;
forming a first contact in the first opening and a third contact in the third opening; and
forming a second contact in the second opening.

17. The method of claim 16, wherein forming the isolation structure includes forming a second active area adjacent the first active area and separated from the first active area by the isolation structure, the method including:
forming a second gate line that extends along the first direction and overlaps the second active area and the isolation structure; and
forming a fourth contact on the second gate line that overlaps the isolation structure and a fifth contact on the second gate line that overlaps the second active area.

18. The method of claim 17, comprising:
forming a first metal layer electrically coupled to the first contact and the second contact, the first metal layer overlapping the second contact; and
forming a second metal layer electrically coupled to the fourth contact and the fifth contact, the second metal layer overlapping the fifth contact.

19. The method of claim 16, wherein forming the first gate line includes:
forming a sacrificial gate line that includes polysilicon;
forming sidewall spacers abutting the sacrificial gate line;
with the sidewall spacers in place, forming an opening between the sidewall spacers by removing the sacrificial gate line;
forming a dielectric layer in the opening; and
forming a metal layer on the dielectric layer in the opening, wherein forming the second opening includes performing a dry etch that removes material of the metal layer exposed by the mask layer.

20. The method of claim 19, wherein forming the second opening includes forming the second opening that has elliptical shape by removing material of the sidewall spacers.
